(19) United States
(12) Patent Application Publication
(10) Pub. No.: US 2012/0211770 A1
(43) Pub. Date: Aug. 23, 2012

(54) SEMICONDUCTOR DEVICE, COMBINED SUBSTRATE, AND METHODS FOR MANUFACTURING THEM

(75) Inventors: Hiromu Shiomi, Osaka-shi (JP); Hideto Tamaso, Osaka-shi (JP)

(73) Assignee: Sumitomo Electric Industries, Ltd., Osaka-shi (JP)

(21) Appl. No.: 13/504,410

(22) PCT Filed: May 2, 2011
(86) PCT No.: PCT/JP2011/060507

§ 371 Date: Apr. 26, 2012

(30) Foreign Application Priority Data
May 14, 2010 (JP) 2010-112414

(51) Int. Cl. H01L 29/24; H01L 29/20; H01L 21/762

(52) U.S. Cl. 257/77; 438/458; 438/455; 257/615; 257/E21.568; 257/E21.567; 257/E29.104; 257/E29.089

(57) ABSTRACT

There are provided a semiconductor device of low cost and high quality, a combined substrate used for manufacturing the semiconductor device, and methods for manufacturing them. The method for manufacturing the semiconductor device includes the steps of: preparing a single-crystal semiconductor member; preparing a supporting base; connecting the supporting base and the single-crystal semiconductor member to each other through a connecting layer containing carbon; forming an epitaxial layer on a surface of the single-crystal semiconductor member; forming a semiconductor element using the epitaxial layer; separating the single-crystal semiconductor member from the supporting base by oxidizing and accordingly decomposing the connecting layer after the step of forming the semiconductor element; and dividing the single-crystal semiconductor member separated from the supporting base.

### TECHNICAL FIELD

The present invention relates to a semiconductor device, a combined substrate, and methods for manufacturing them. More particularly, the present invention relates to a combined substrate constructed by combining a single-crystal semiconductor member with a supporting base; a semiconductor device manufactured using the combined substrate; and methods for manufacturing them.

### BACKGROUND ART

Conventionally, there has been proposed a semiconductor device constructed by connecting a supporting base to a semiconductor layer having an element structure formed thereon (for example, Japanese Patent Laying-Open No. 2007-158133 (hereinafter, referred to as Patent Literature 1)). Also, a method for manufacturing a semiconductor device has been proposed which includes the step of connecting another supporting base to a semiconductor layer formed on a growth substrate and removing the growth substrate from the semiconductor layer (for example, see Japanese Patent Laying-Open No. 2006-173582 (hereinafter, referred to as Patent Literature 2)). In Patent Literature 1, a nitride semiconductor layer is formed on a sapphire substrate to constitute a light emitting element structure. Then, onto the nitride semiconductor layer, a silicon substrate, which is another supporting base, is connected using a solder. Thereafter, the sapphire substrate is removed. In this way, efficiency in extracting light is improved. On the other hand, in Patent Literature 2, a GaN-HEMT, which is a lateral type device, is formed on a sapphire substrate with a buffer layer interposed therebetween. A supporting substrate is connected to the GaN-HEMT side. Then, the sapphire substrate is detached and the buffer layer is removed, thereby exposing the backside surface of a carrier running layer of the GaN-HEMT. Then, an electrode for emitting holes is formed on the backside surface thereof, thereby improving breakdown voltage of the element.

### CITATION LIST

Patent Literature
PTL 1: Japanese Patent Laying-Open No. 2007-158133
PTL 2: Japanese Patent Laying-Open No. 2006-173582

### SUMMARY OF INVENTION

### Technical Problem

Each of the semiconductor devices using the nitride semiconductors as disclosed in Patent Literatures 1 and 2 described above may be a vertical type power device. Such a vertical type power device is required to have reduced on-resistance. However, neither Patent Literature 1 nor 2 particularly recites reduction of the on-resistance. In order to attain reduced on-resistance in such a vertical type power device, the present inventor has conducted a study of reducing the thickness of the substrate having an element structure thereon after formation of the device (for example, cutting the substrate from its backside surface side). However, when processing the substrate, the element structure is likely to have damaged, disadvantageously.

Further, in a compound semiconductor such as the nitride semiconductor described above, the number of devices that can be manufactured at one time is limited because the substrate, which is available as a high-quality single-crystal substrate, has a size smaller than that of a silicon substrate. This makes it difficult to reduce the manufacturing cost, disadvantageously.

The present invention has been made to solve the foregoing problems, and has its object to provide a semiconductor device of low cost and high quality, a combined substrate used to manufacture the semiconductor device, and methods for manufacturing them.

### Solution to Problem

A method for manufacturing a semiconductor device in the present invention includes the steps of: preparing a single-crystal semiconductor member; preparing a supporting base; connecting the supporting base and the single-crystal semiconductor member to each other through a connecting layer containing carbon; forming an epitaxial layer on a surface of the single-crystal semiconductor member; forming a semiconductor element using the epitaxial layer; separating the single-crystal semiconductor member from the supporting base by oxidizing and accordingly decomposing the connecting layer after the step of forming the semiconductor element; and dividing the single-crystal semiconductor member separated from the supporting base.

In this case, the step of forming the semiconductor element can be performed using the combined substrate in which the single-crystal semiconductor member is connected to the supporting base. Hence, in this step, the single-crystal semiconductor member can be handled more readily. Further, the process in the step of forming the semiconductor element is performed with the single-crystal semiconductor member being connected to the supporting base. Hence, the single-crystal semiconductor member does not need to necessarily secure a thickness with which the single-crystal semiconductor member can stand by itself. The thickness thereof can be determined in view of characteristics (such as on-resistance) of a final product of the semiconductor element. Thus, in order to reduce the on-resistance for example, the thickness of the single-crystal semiconductor member can be set at a thickness smaller than the lower limit of a thickness with which the single-crystal semiconductor member can stand by itself. As a result, there can be realized a semiconductor device having excellent characteristics (for example, sufficiently low on-resistance).

Further, the connecting layer for connecting the single-crystal semiconductor member to the supporting base contains carbon. Hence, the connecting layer can be readily decomposed when being oxidized. Accordingly, the single-crystal semiconductor member can be readily separated from the supporting base after forming the semiconductor element on the single-crystal semiconductor member.

Further, the connecting layer containing carbon is preferably a connecting layer containing carbon as its main component. For example, as the connecting layer, a substantially solid-state carbon layer can be used which is obtained by thermally treating (carbonizing) a photoresist or a resin for solidification thereof. Such a connecting layer containing carbon as its main component can sufficiently maintain the connection between the single-crystal semiconductor member and the supporting base even at a heat treatment temperature (for example, approximately 1000° C.) in the step of forming the semiconductor element, as long as the connecting layer is not exposed to oxidizing atmosphere.

A method for manufacturing a combined substrate in the present invention includes the steps of: preparing a single-crystal semiconductor member; preparing a supporting base; and connecting the supporting base and the single-crystal semiconductor member to each other through a connecting layer containing carbon.

In this way, because the supporting base is connected to the single-crystal semiconductor member, the combined substrate can be handled well even when the thickness of the single-crystal semiconductor member is thin. Further, the process of forming the semiconductor element on the SiC single-crystal substrate of the combined substrate is performed with the single-crystal semiconductor member being connected to the supporting base. Hence, the single-crystal semiconductor member does not need to necessarily secure a thickness with which the single-crystal semiconductor member can stand by itself. The thickness of the single-crystal semiconductor member can be determined in view of characteristics (such as on-resistance) of a final product of the semiconductor element. Thus, in order to reduce the on-resistance for example, the thickness of the single-crystal semiconductor member can be set at a thickness smaller than the lower limit of a thickness with which the single-crystal semiconductor member can stand by itself. As a result, according to the present invention, there can be obtained a combined substrate by which a semiconductor device having excellent characteristics (for example, sufficiently low on-resistance) can be manufactured.

Further, the connecting layer for connecting the single-crystal semiconductor member to the supporting base contains carbon. Hence, the connecting layer can be readily decomposed when being oxidized. Accordingly, the single-crystal semiconductor member can be readily separated from the supporting base.

A semiconductor device according to the present invention includes a supporting base, a single-crystal semiconductor layer, and an electrode. The single-crystal semiconductor layer is connected onto a surface of the supporting base through a connecting layer containing carbon. The electrode is formed on the single-crystal semiconductor layer. In this way, the supporting base can be used as a reinforcement member. Hence, only a minimum thickness required for operation of the device may be secured for the thickness of the high-quality single-crystal semiconductor layer. Accordingly, the thickness of the single-crystal semiconductor layer can be thinner than that in the case of forming a semiconductor device only using a single-crystal semiconductor. As a result, the manufacturing cost of the semiconductor device can be reduced. It should be noted that the single-crystal semiconductor layer may include, for example, a single-crystal semiconductor member connected onto the surface of the supporting base through the connecting layer; and an epitaxial layer formed on a surface of the single-crystal semiconductor member.

A combined substrate according to the present invention includes a supporting base, and a single-crystal semiconductor member. The single-crystal semiconductor member is connected onto a surface of the supporting base through a connecting layer containing carbon.

In this way, because the supporting base is connected to the single-crystal semiconductor member, the combined substrate can be handled well even when the thickness of the single-crystal semiconductor member is thin. Further, the process of forming the semiconductor element on the single-crystal semiconductor member of the combined substrate is performed with the single-crystal semiconductor member being connected to the supporting base. Hence, the single-crystal semiconductor member does not need to necessarily secure a thickness with which the single-crystal semiconductor member can stand by itself. The thickness of the single-crystal semiconductor member can be determined in view of characteristics (such as on-resistance) of a final product of the semiconductor element. Thus, in order to reduce the on-resistance for example, the thickness of the single-crystal semiconductor member can be set at a thickness smaller than the lower limit of a thickness with which the single-crystal semiconductor member can stand by itself. As a result, when using the combined substrate according to the present invention, there can be realized a semiconductor device having excellent characteristics (for example, sufficiently low on-resistance).

Further, the connecting layer for connecting the single-crystal semiconductor member to the supporting base contains carbon. Hence, the connecting layer can be readily decomposed when being oxidized. Accordingly, the single-crystal semiconductor member can be readily separated from the supporting base.

### Advantageous Effects of Invention

The present invention can provide a semiconductor device of low cost and high quality, and a combined substrate suitable for manufacturing of the semiconductor device.

### BRIEF DESCRIPTION OF DRAWINGS

FIG. 1 is a flowchart for illustrating a first embodiment of a method for manufacturing a semiconductor device according to the present invention.

FIG. 2 is a schematic view for illustrating the method for manufacturing the semiconductor device as shown in FIG. 1.

FIG. 3 is a schematic view for illustrating the method for manufacturing the semiconductor device as shown in FIG. 1.

FIG. 4 is a schematic view for illustrating the method for manufacturing the semiconductor device as shown in FIG. 1.

FIG. 5 is a schematic view for illustrating the method for manufacturing the semiconductor device as shown in FIG. 1.

FIG. 6 is a schematic view for illustrating the method for manufacturing the semiconductor device as shown in FIG. 1.

FIG. 7 is a schematic view for illustrating the method for manufacturing the semiconductor device as shown in FIG. 1.

FIG. 8 is a schematic view for illustrating a first variation of the method for manufacturing the semiconductor device as shown in FIG. 1.

FIG. 9 is a schematic view for illustrating a second variation of the method for manufacturing the semiconductor device as shown in FIG. 1.

FIG. 10 is a schematic view of a second embodiment of the method for manufacturing the semiconductor device according to the present invention.

FIG. 11 is a schematic view showing the second embodiment of the method for manufacturing the semiconductor device according to the present invention.

FIG. 12 is a schematic view showing the second embodiment of the method for manufacturing the semiconductor device according to the present invention.

FIG. 13 is a schematic view showing the second embodiment of the method for manufacturing the semiconductor device according to the present invention.

FIG. 14 is a schematic view showing the second embodiment of the method for manufacturing the semiconductor device according to the present invention.

FIG. 15 is a schematic view showing the second embodiment of the method for manufacturing the semiconductor device according to the present invention.

FIG. 16 is a schematic view for illustrating a first variation of the second embodiment of the method for manufacturing the semiconductor device according to the present invention.

FIG. 17 is a schematic view for illustrating a second variation of the second embodiment of the method for manufacturing the semiconductor device according to the present invention.

FIG. 18 is a schematic view for illustrating a third embodiment of the method for manufacturing the semiconductor device according to the present invention.

FIG. 19 is a schematic view for illustrating the third embodiment of the method for manufacturing the semiconductor device according to the present invention.

FIG. 20 is a schematic view for illustrating the third embodiment of the method for manufacturing the semiconductor device according to the present invention.

FIG. 21 is a schematic view for illustrating the third embodiment of the method for manufacturing the semiconductor device according to the present invention.

FIG. 22 is a schematic view for illustrating the third embodiment of the method for manufacturing the semiconductor device according to the present invention.

FIG. 23 is a schematic view for illustrating the third embodiment of the method for manufacturing the semiconductor device according to the present invention.

FIG. 24 is a schematic view for illustrating the third embodiment of the method for manufacturing the semiconductor device according to the present invention.

FIG. 25 is a schematic view for illustrating the third embodiment of the method for manufacturing the semiconductor device according to the present invention.

FIG. 26 is a schematic view for illustrating the third embodiment of the method for manufacturing the semiconductor device according to the present invention.

FIG. 27 is a flowchart for illustrating a fourth embodiment of the method for manufacturing the semiconductor device according to the present invention.

FIG. 28 is a schematic view for illustrating the method for manufacturing the semiconductor device as shown in FIG. 27.

FIG. 29 is a schematic view for illustrating the method for manufacturing the semiconductor device as shown in FIG. 27.

FIG. 30 is a schematic cross sectional view showing a semiconductor device obtained according to a fifth embodiment of the method for manufacturing the semiconductor device according to the present invention.

FIG. 31 is a flowchart for illustrating the fifth embodiment of the method for manufacturing the semiconductor device according to the present invention.

FIG. 32 is a schematic cross sectional view showing a semiconductor device obtained according to the method for manufacturing the semiconductor device according to the present invention.

### DESCRIPTION OF EMBODIMENTS

The following describes embodiments of the present invention with reference to figures. It should be noted that in the below-mentioned figures, the same or corresponding portions are given the same reference characters and are not described repeatedly.

### First Embodiment

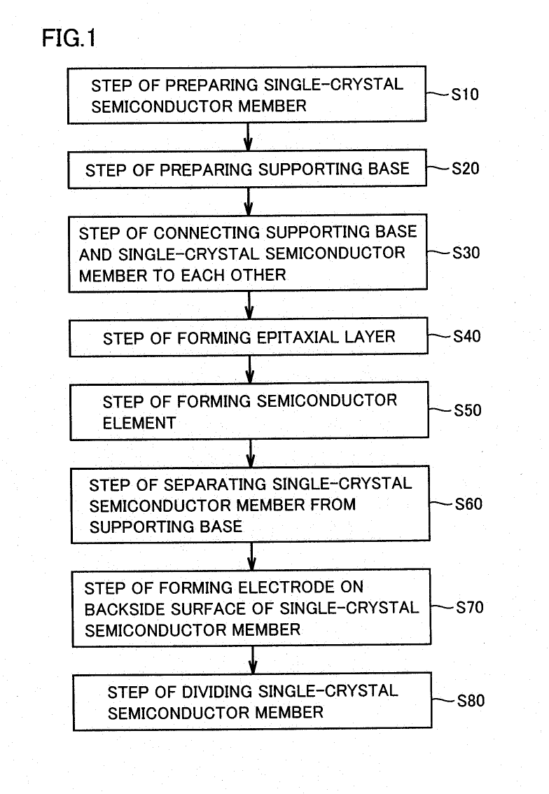

The following describes a method for manufacturing a semiconductor device according to the present invention, with reference to FIG. 1 to FIG. 7.

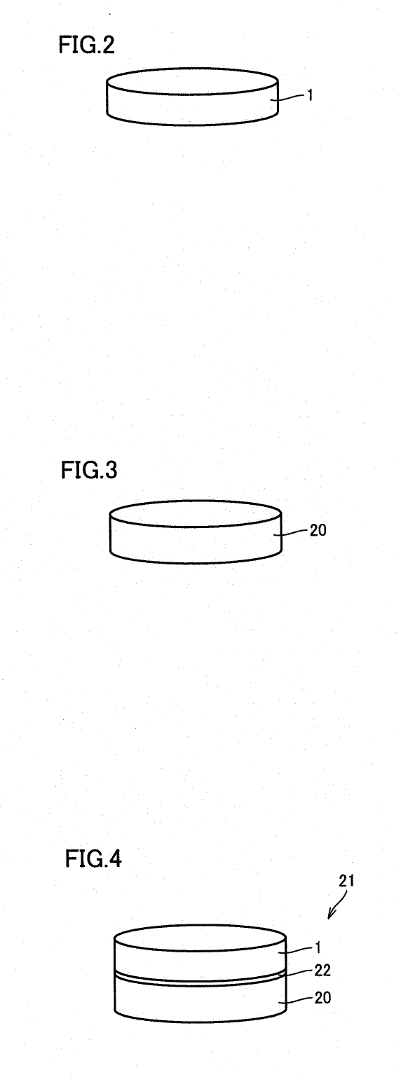

As shown in FIG. 1, in the method for manufacturing the semiconductor device according to the present invention, a step (S10) of preparing a single-crystal semiconductor member is performed. Specifically, a silicon carbide (SiC) single-crystal substrate 1, which is one exemplary single-crystal semiconductor member, is prepared as shown in FIG. 2. SiC single-crystal substrate 1 shown in FIG. 2 has a circular planar shape, but may have any planar shape. It should be noted that as the single-crystal semiconductor member, a gallium nitride (GaN) single-crystal substrate or the like may be used apart from SiC single-crystal substrate 1 described above, for example.

Next, as shown in FIG. 1, a step (S20) of preparing a supporting base is performed. Specifically, as shown in FIG. 3, a supporting base 20 is prepared. Supporting base 20 shown in FIG. 3 has a planar shape similar to that of SiC single-crystal substrate 1 shown in FIG. 2. For example, supporting base 20 has a circular planar shape. Further, supporting base 20 may have an upper surface having the same size as that of the bottom surface of SiC single-crystal substrate 1 shown in FIG. 2. Preferably, the upper surface of supporting base 20 may have a larger size than that of the bottom surface of SiC single-crystal substrate 1. Further, supporting base 20 can be made of any material as long as the material is capable of withstanding a process temperature in a process to be provided to SiC single-crystal substrate 1 described above. A usable example thereof is SiC.

Next, as shown in FIG. 1, a step (S30) of connecting the supporting base and the single-crystal semiconductor member to each other is performed. Specifically, as shown in FIG. 4, the upper surface of supporting base 20 and the backside surface of SiC single-crystal substrate 1 are connected to each other through a connecting layer 22. Connecting layer 22 is an adhesive layer containing carbon. Connecting layer 22 is formed in the following manner. For example, a carbon-containing material (resin-made material such as a resist) is disposed on the upper surface of supporting base 20. Then, SiC single-crystal substrate 1 is mounted on the surface thereof having the carbon-containing material thus disposed thereon. In this state, heat treatment is performed to solidify the carbon-containing material into a solid containing carbon as its main component. For example, when a resist is used as the material, the following heat treatment can be applied. First, the resist is solidified at a predetermined temperature (for example, 100° C.). Then, while applying predetermined pressure and load in the vertical direction in a vacuum furnace, high-temperature heat treatment (for example, heat treatment at a temperature of approximately 800° C.) is performed to form the resist into connecting layer 22 that is in a solid state and that contains carbon as its main component. Accordingly, combined substrate 21 shown in FIG. 4 is obtained.

Next, as shown in FIG. 1, a step (S40) of forming an epitaxial layer is performed. Specifically, an epitaxial layer is formed on a surface of SiC single-crystal substrate 1 of combined substrate 21 shown in FIG. 4, using an epitaxial growth method.

Next, as shown in FIG. 1, a step (S50) of forming a semiconductor element is performed. Specifically, using the above-described epitaxial layer, a semiconductor element having a predetermined structure is formed on the surface of SiC single-crystal substrate 1. As a result, as shown in FIG. 5, an element 30 is formed on the surface of SiC single-crystal substrate 1. It is preferable that a plurality of elements 30 are formed.

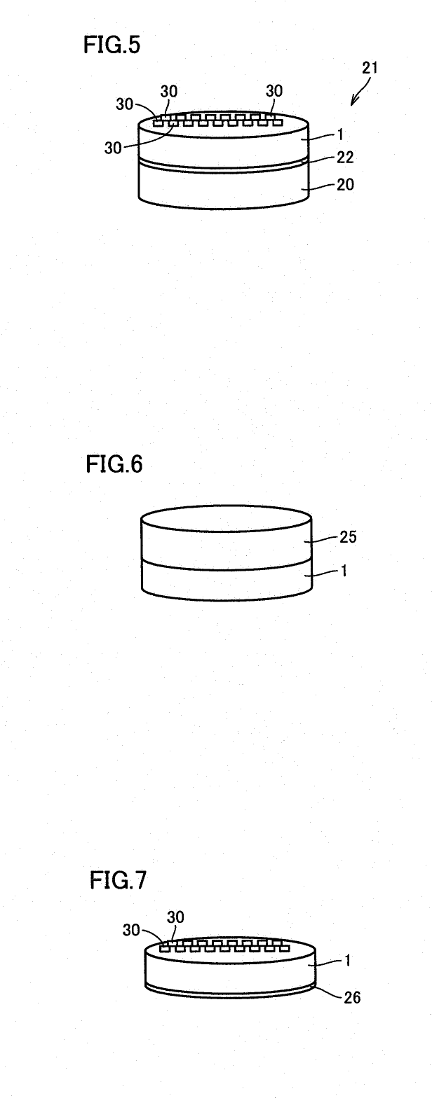

Next, as shown in FIG. 1, a step (S60) of separating the single-crystal semiconductor member from the supporting base is performed. Specifically, as shown in FIG. 6, a second supporting base 25 is connected onto the surface of SiC single-crystal substrate 1 on which elements 30 are formed. This second supporting base 25 can be connected thereonto using any method. An exemplary method is to use a heat-resistant tape to achieve the connection between second supporting base 25 and SiC single-crystal substrate 1. In this state, a process capable of selectively removing connecting layer 22 is performed. Specifically, for example, combined substrate 21 having second supporting base 25 connected thereto is placed in oxygen plasma to decompose and remove connecting layer 22 containing carbon. Accordingly, as shown in FIG. 6, SiC single-crystal substrate 1 can be separated from supporting base 20.

Next, as shown in FIG. 1, a step (S70) of forming an electrode on the backside surface of the single-crystal semiconductor member is performed. Specifically, as shown in FIG. 7, a backside electrode 26 is formed on the backside surface of SiC single-crystal substrate 1. Backside electrode 26 can be formed using any method, such as a sputtering method. Further, backside electrode 26 can be made of any material, such as a conductor like a metal. It should be noted that the following steps may be performed in advance before forming backside electrode 26: a step of implanting a conductive impurity into the backside surface of SiC single-crystal substrate 1; and a step of performing heat treatment for activation.

Next, as shown in FIG. 1, a step (S80) of dividing the single-crystal semiconductor member is performed. Specifically, in order to separate elements 30 formed on the surface of SiC single-crystal substrate 1 from one another, SiC single-crystal substrate 1 are divided into predetermined sizes using, for example, a dicing device or the like. As a result, elements 30 can be separated from one another. In this way, semiconductor devices according to the present invention can be obtained.

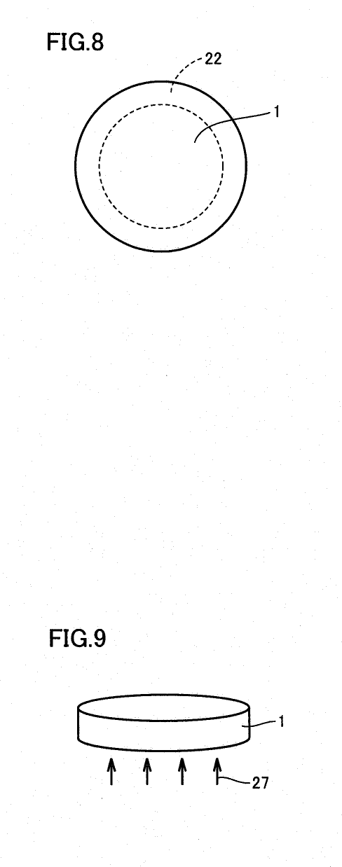

In step (S30) of connecting the supporting base and the single-crystal semiconductor member to each other in the method for manufacturing the semiconductor device, the carbon-containing material to be formed into connecting layer 22 is disposed to cover the upper surface of supporting base 20, but the material may be disposed in a different manner. Specifically, connecting layer 22 may be disposed only in a part of the connection interface between supporting base 20 and SiC single-crystal substrate 1, as long as SiC single-crystal substrate 1 and supporting base 20 can be connected and fixed to each other. For example, as shown in FIG. 8, connecting layer 22 may be provided only at the outer circumferential portion of SiC single-crystal substrate 1. FIG. 8 is a schematic planar view showing another exemplary provision of the connecting layer in step (S30) of connecting the supporting base and the single-crystal semiconductor member to each other.

FIG. 8, which is a schematic planar view showing the another exemplary provision of the connecting layer in step (S30) of connecting the supporting base and the single-crystal semiconductor member to each other, is also a perspective planar view showing another example of combined substrate 21 shown in FIG. 4 when viewed from above. Referring to FIG. 8, connecting layer 22 is disposed only at the outer circumferential portion of combined substrate 21 (the outer circumferential portion of the connection interface between supporting base 20 and SiC single-crystal substrate 1).

In this case, in step (S60) of separating the single-crystal semiconductor member from the supporting base as shown in FIG. 1, connecting layer 22 is readily subjected to plasma atmosphere for removing connecting layer 22 such as oxygen plasma or other reactive atmosphere. Accordingly, in step (S60), SiC single-crystal substrate 1 can be removed from supporting base 20 more quickly.

Referring to FIG. 9, in step (S10) of preparing the single-crystal semiconductor member as shown in FIG. 1, ion implantation may be performed into the backside surface of SiC single-crystal substrate 1 (surface to be connected to supporting base 20) as indicated by arrows 27. With such ion implantation, backside electrode 26 to be formed in step (S70) of forming the backside electrode of the single-crystal semiconductor member will be more securely brought into ohmic contact with the backside surface of SiC single-crystal substrate 1. It is preferable to perform heat treatment for activation of the implanted ions after the ion implantation. After the heat treatment for activation, step (S30) and subsequent steps shown in FIG. 1 are performed.

### Second Embodiment

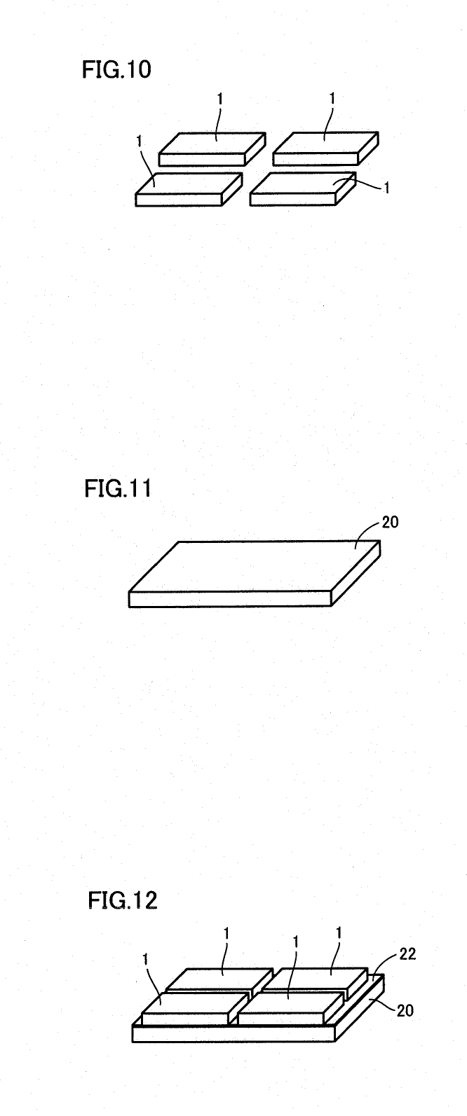

Referring to FIG. 10 to FIG. 15, a second embodiment of the method for manufacturing the semiconductor device according to the present invention will be described.

The second embodiment of the method for manufacturing the semiconductor device according to the present invention as shown in FIG. 10 to FIG. 15 is basically the same as the first embodiment of the method for manufacturing the semiconductor device according to the present invention as shown in FIG. 1-FIG. 7, but is different therefrom in terms of respective shapes of SiC single-crystal substrate 1 and supporting base 20 as well as a shape of combined substrate 21 obtained by combining them. Specifically, in step (S10) of preparing the single-crystal semiconductor member (see FIG. 1), as shown in FIG. 10, a plurality of SiC single-crystal substrates 1 each having a quadrangular planar shape are prepared. Here, four SiC single-crystal substrates 1 are prepared.

Next, in step (S20) of preparing the supporting base, as shown in FIG. 11, a supporting base 20 is prepared which has a quadrangular planar shape with a planar size relatively larger than that of each of SiC single-crystal substrates 1 so as to allow the plurality of SiC single-crystal substrates 1 to be mounted thereon. Supporting base 20 can be made of the same material as that of supporting base 20 shown in FIG. 3. It should be noted that the shape of supporting base 20 may be the same as that of supporting base 20 shown in FIG. 3.

Next, step (S30) of connecting the supporting base and the single-crystal semiconductor member to each other is performed. Specifically, as shown in FIG. 12, a layer to be formed into connecting layer 22 containing carbon is formed on the upper surface of supporting base 20. Then, the plurality of SiC single-crystal substrates 1 are mounted onto the layer, and then predetermined heat treatment is performed to form the layer into connecting layer 22. Accordingly, connecting layer 22 thus formed provides a combined substrate constituted by supporting base 20 to which the plurality of SiC single-crystal substrates 1 are connected. On this occasion, as shown in FIG. 12, SiC single-crystal substrates 1 arranged side by side on the upper surface of supporting base 20 may be disposed with a space interposed therebetween, or may be disposed with their end surfaces making contact with each other. In the case where SiC single-crystal substrates 1 are disposed with a space interposed therebetween as shown in FIG. 12, reaction atmosphere such as oxygen plasma can readily reach connecting layer 22 located at the connection interface between each of SiC single-crystal substrates 1 and supporting base 20 in subsequent step (S60) of separating the single-crystal semiconductor member from the supporting base. Thus, SiC single-crystal substrates 1 can be readily detached from supporting base 20.

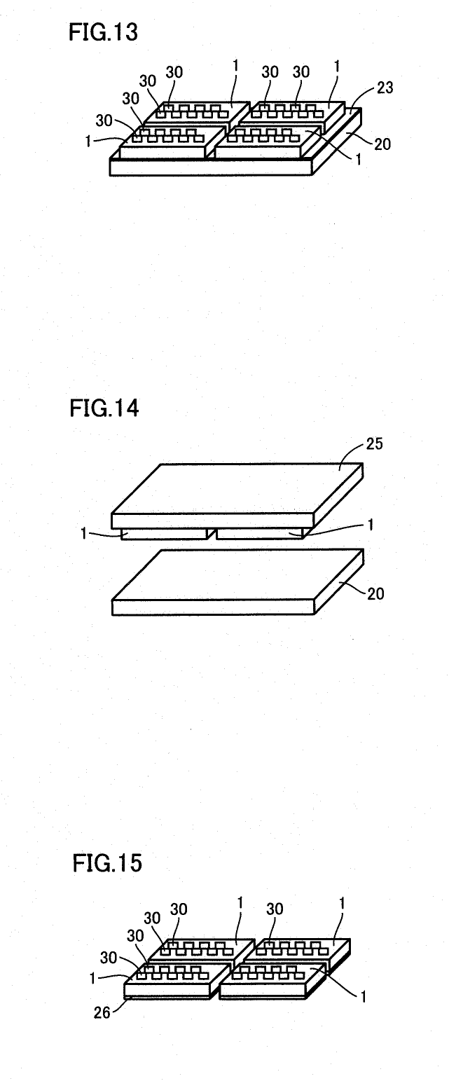

Next, step (S40) of forming the epitaxial layer is performed. Accordingly, as shown in FIG. 13, epitaxial layer 23 is formed on the upper surfaces of the SiC single-crystal substrates and connecting layer 22 located on the upper surface of supporting base 20. Accordingly, the surface of connecting layer 22 at the connection portion between each of SiC single-crystal substrates 1 and supporting base 20 is covered with epitaxial layer 23.

Thereafter, as with the first embodiment described above, step (S50) of forming the semiconductor element is performed. In this step (S50), the same processing conditions as those of step (S50) in the above-described first embodiment can be used.

Then, step (S60) of separating the single-crystal semiconductor member from the supporting base as shown in FIG. 1 is performed. Specifically, as shown in FIG. 14, as with the first embodiment, second supporting base 25 is connected onto the upper surfaces of SiC single-crystal substrates 1 by means of any method such as utilization of a heat-resistant tape. Thereafter, combined substrate 21 is placed in atmosphere such as oxygen plasma, thereby decomposing and removing connecting layer 22 located between each of SiC single-crystal substrates 1 and supporting base 20. It should be noted that because epitaxial layer 23 (see FIG. 12) is formed to cover connecting layer 22 as described above, a step of removing epitaxial layer 23 from the vicinity of the connection portion between each of SiC single-crystal substrates 1 and supporting base 20 is performed in advance before adhering second supporting base 25 to the upper surfaces of SiC single-crystal substrates 1. In this step, for example, epitaxial layer 23 is removed by any method such as reactive ion etching (RIE), using a mask layer (such as a resist film having a pattern) exposing only the vicinity of the above-described connection portion.

Next, step (S70) of forming the electrode on the backside surface of single-crystal semiconductor member as shown in FIG. 1 is performed. This step (S70) is basically the same as step (S70) of the first embodiment. Accordingly, as shown in FIG. 15, backside electrode 26 can be formed on the backside surface of SiC single-crystal substrate 1.

Thereafter, as with the first embodiment, step (S80) of dividing the single-crystal semiconductor member is performed, thereby obtaining semiconductor devices according to the present invention.

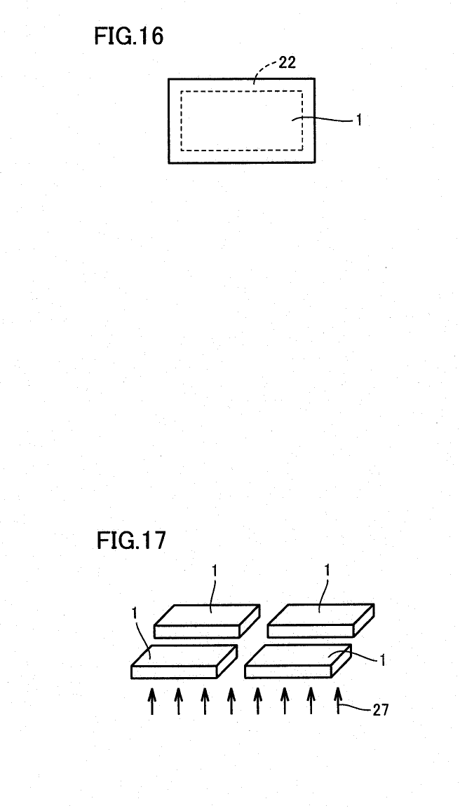

Referring to FIG. 16, the following describes a first variation of the second embodiment of the method for manufacturing the semiconductor device according to the present invention. It should be noted that FIG. 16 corresponds to FIG. 8.

As shown in FIG. 16, in step (S30) of connecting the supporting base and the single-crystal semiconductor member to each other, connecting layer 22 may be formed only at the outer circumferential portion of the connection interface between each of SiC single-crystal substrates 1 and supporting base 20. Also in this case, the same effect can be provided as that in the case of employing the provision of connecting layer 22 shown in FIG. 8.

Referring to FIG. 17, the following describes a second variation of the second embodiment of the method for manufacturing the semiconductor device according to the present invention. It should be noted that FIG. 17 corresponds to FIG. 9.

In step (S10) of preparing the single-crystal semiconductor member as shown in FIG. 1, as shown in FIG. 17, ion implantation may be performed in advance into the backside surface of each of SiC single-crystal substrates 1 as indicated by arrows 27. Further, it is preferable to perform an annealing process for activation after the ion implantation. Also in this way, the same effect can be obtained as that in the case where the step illustrated in FIG. 9 is performed.

### Third Embodiment

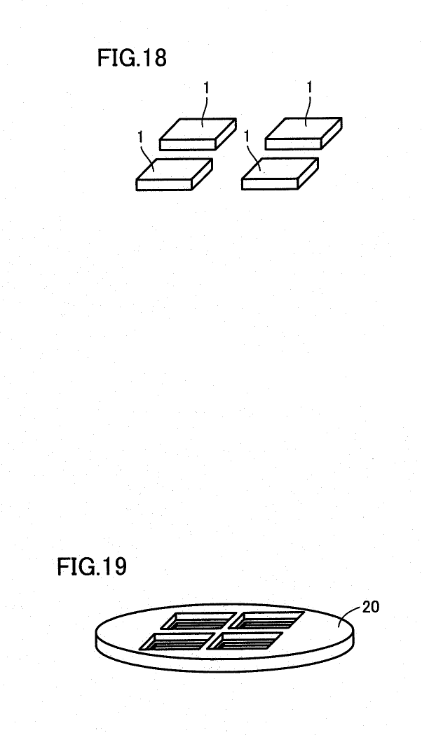

Referring to FIG. 18-FIG. 26, the following describes a third embodiment of the method for manufacturing the semiconductor device according to the present invention.

The method for manufacturing the semiconductor device as shown in FIG. 18-FIG. 26 includes basically the same steps as those of the method for manufacturing the semiconductor device according to the present invention in the first embodiment as shown in FIG. 1-FIG. 7, but is different from respective shapes of SiC single-crystal substrate 1 (see FIG. 18) and supporting base 20. As a result, combined substrate 21 has a different shape. This will be described specifically below.

First, step (S10) of preparing the single-crystal semiconductor member as shown in FIG. 1 is performed. A specific process therein is similar to the step illustrated in FIG. 2, but is different from that in the method for manufacturing the semiconductor device as shown in FIG. 1, in terms of size and shape of SiC single-crystal substrate 1. Specifically, as shown in FIG. 18, SiC single-crystal substrates 1 each in the form of a plate having a quadrangular planar shape are prepared as the single-crystal semiconductor member.

Next, step (S20) of preparing the supporting base is performed. Specifically, a supporting base 20 is prepared which has a circular planar shape and having openings 41 therein as shown in FIG. 19. Each of openings 41 formed in supporting base 20 has a planar shape analogue to that of each of SiC single-crystal substrates 1 shown in FIG. 18. Further, at the upper portion of opening 41, a stepped portion 42 is formed to have a width relatively wider than that of opening 41. Stepped portion 42 has a size set to receive SiC single-crystal substrate 1 therein. In other words, the size of the planar shape of stepped portion 42 corresponds to a size obtained by adding the thickness of connecting layer 22 (see FIG. 22) to the size of planar shape of SiC single-crystal substrate 1.

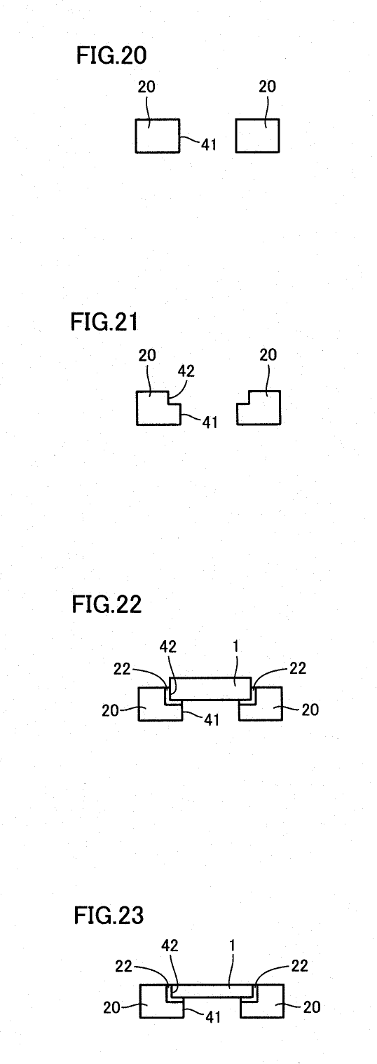

This opening can be formed in the following manner. That is, first, as shown in FIG. 20 and FIG. 21, opening 41 is formed to extend through supporting base 20. The planar shape of opening 41 can be for example a quadrangular shape. Thereafter, as shown in FIG. 21, at the upper end of opening 41, stepped portion 42 is formed to provide a wider opening. The planar shape of stepped portion 42 is quadrangular, and is similar to that of SiC single-crystal substrate 1 shown in FIG. 18. The plurality of openings 41 are formed in supporting base 20. In supporting base 20 shown in FIG. 19, four openings 41 are formed.

Next, step (S30) of connecting the supporting base and the single-crystal semiconductor member to each other is performed. Specifically, as shown in FIG. 22 and FIG. 23, each of SiC single-crystal substrates 1 is fit into each of stepped portions 42 formed at the upper portions of openings 41 of supporting base 20. In doing so, as shown in FIG. 22, a layer (such as a resist) to be formed into connecting layer 22 containing carbon is provided in advance at the inner circumference side of stepped portion 42. Thereafter, SiC single-crystal substrate 1 is fit into stepped portion 42. As the layer to be formed into connecting layer 22, for example, a liquid-state material can be used. Then, predetermined heat treatment is performed to form the layer into connecting layer 22, which is a layer in solid state and contains carbon. As a result, the structure shown in FIG. 22 is obtained. It should be noted that SiC single-crystal substrates 1 are installed in the same manner in all the openings of supporting base 20 shown in FIG. 19. It should be also noted that stepped portion 42 has a depth smaller than the thickness of SiC single-crystal substrate 1.

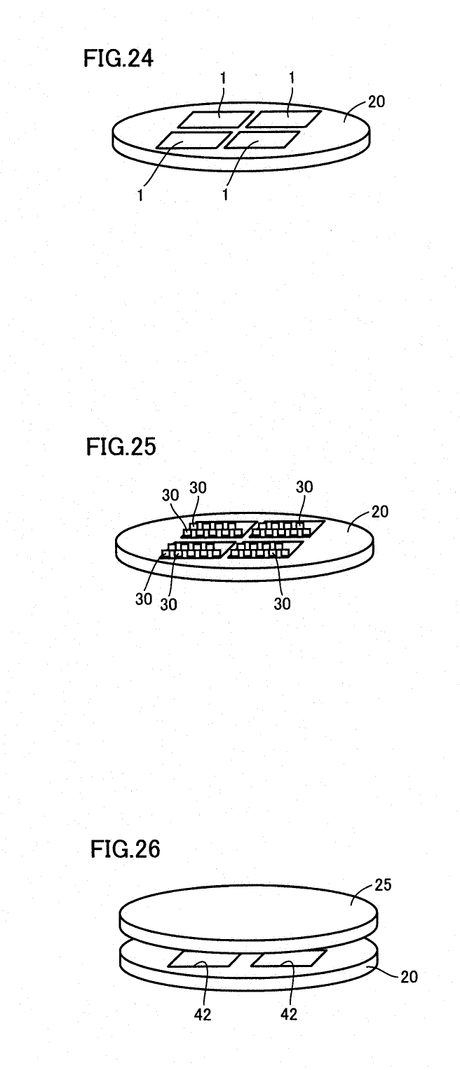

Thereafter, as shown in FIG. 23, the surface layer of SiC single-crystal substrate 1 is removed by performing, for example, a polishing process. As a result, there can be obtained a structure in which the surface of supporting base 20 and the surface of SiC single-crystal substrate 1 come level with each other as shown in FIG. 23. In this way, a combined substrate 21 shown in FIG. 24 can be obtained. It should be noted that each of FIG. 20 to FIG. 23 is a schematic cross sectional view taken along a line XX-XX in FIG. 19.

Thereafter, step (S40) of forming the epitaxial layer and step (S50) of forming the semiconductor element as shown in FIG. 1 are performed. As a result, as shown in FIG. 25, a plurality of elements 30 using the above-described epitaxial layer are formed on the surface of SiC single-crystal substrate 1.

Thereafter, step (S60) of separating the single-crystal semiconductor member from the supporting base as shown in FIG. 1 is performed. Specifically, a second supporting base 25 is connected to the upper surfaces of SiC single-crystal substrates 1 each having the plurality of elements 30 formed thereon. Thereafter, oxygen plasma treatment or the like is performed to decompose and remove connecting layer 22 containing carbon. As a result, as shown in FIG. 26, second supporting base 25 and SiC single-crystal substrate 1 can be separated from supporting base 20.

Thereafter, step (S70) of forming the backside electrode of the single-crystal semiconductor member and step (S80) of dividing the single-crystal semiconductor member as shown in FIG. 1 are performed to obtain semiconductor devices of the present invention.

It should be noted that an ion implantation step may be performed to the backside surfaces of SiC single-crystal substrates 1 shown in FIG. 18 before being connected to supporting base 20, as shown in FIG. 17. Then, an annealing process for activation may be performed.

### Fourth Embodiment

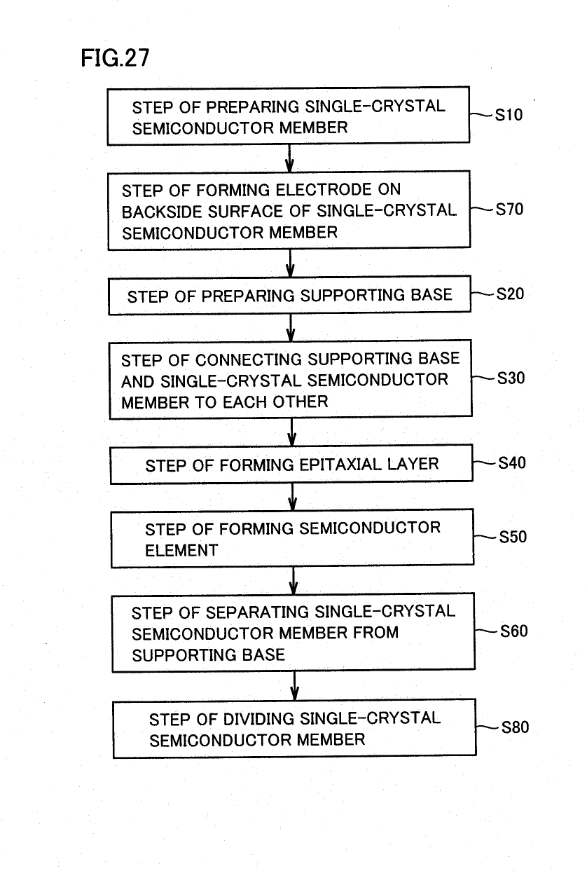

Referring to FIG. 27-FIG. 29, the following describes a fourth embodiment of the method for manufacturing the semiconductor device according to the present invention.

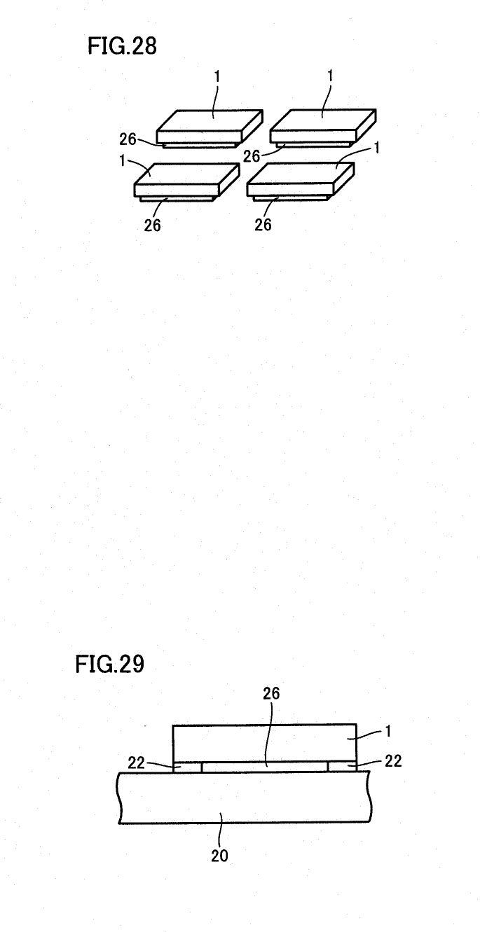

Step (S10) of preparing the single-crystal semiconductor member as shown in FIG. 27 is basically the same as step (S10) in the second embodiment of the method for manufacturing the semiconductor device according to the present invention. In the case, ion implantation and annealing process for activation are provided to the backside surfaces of SiC single-crystal substrates 1 serving as the single-crystal semiconductor member. Thereafter, as shown in FIG. 27, step (S70) of forming the backside electrode of the single-crystal semiconductor member is performed. Specifically, as shown in FIG. 28, a backside electrode 26 is formed on the backside surface of each of SiC single-crystal substrates 1. Backside electrode 26 has a planar size smaller than that of backside surface of SiC single-crystal substrate 1. Such a backside electrode 26 can be formed through, for example, the following step. First, using a photolithography method or the like, a resist mask is formed to have openings corresponding to regions at which backside electrodes 26 are to be formed in the backside surfaces of SiC single-crystal substrates 1. Thereafter, using a sputtering method or the like, a conductor film (such as a metal film) to be the backside electrode is formed on each of the backside surfaces thereof. Then, a portion of the conductor film formed on the resist mask is removed together with the resist mask (lift-off). In this way, backside electrode 26 can be formed. As a result, the structure shown in FIG. 28 is obtained.

Next, as shown in FIG. 27, step (S20) of preparing the supporting base is performed. This step is basically the same as step (S20) in the second embodiment of the present invention.

Next, as shown in FIG. 27, step (S30) of connecting the supporting base and the single-crystal semiconductor member to each other is performed. Specifically, a film to be formed into a connecting layer 22 containing carbon is formed on the backside surface of SiC single-crystal substrate 1 at its outer circumferential portion where backside electrode 26 is not formed, so as to connect the surface of the supporting base and SiC single-crystal substrate 1 to each other. Thereafter, predetermined heat treatment is performed to form the film into connecting layer 22 containing carbon. As a result, a combined substrate can be obtained in which SiC single-crystal substrates 1 are connected onto the surface of supporting base 20 as shown in FIG. 29. On this occasion, as shown in FIG. 29, the outer circumference of backside electrode 26 is surrounded by connecting layer 22. Hence, backside electrode 26 will be never exposed to film formation atmosphere or etching atmosphere in subsequent processes. Further, connecting layer 22 may be disposed in a region between backside electrode 26 and supporting base 20 as long as backside electrode 26 is embedded in connecting layer 22.

Thereafter, step (S40) of forming the epitaxial layer, step (S50) of forming the semiconductor element, step (S60) of separating the single-crystal semiconductor member from the supporting base, and step (S80) of dividing the single-crystal semiconductor member are performed in the same manners as those in the method for manufacturing the semiconductor device in the second embodiment of the present invention. Also in this way, semiconductor devices according to the present invention can be obtained.

### Fifth Embodiment

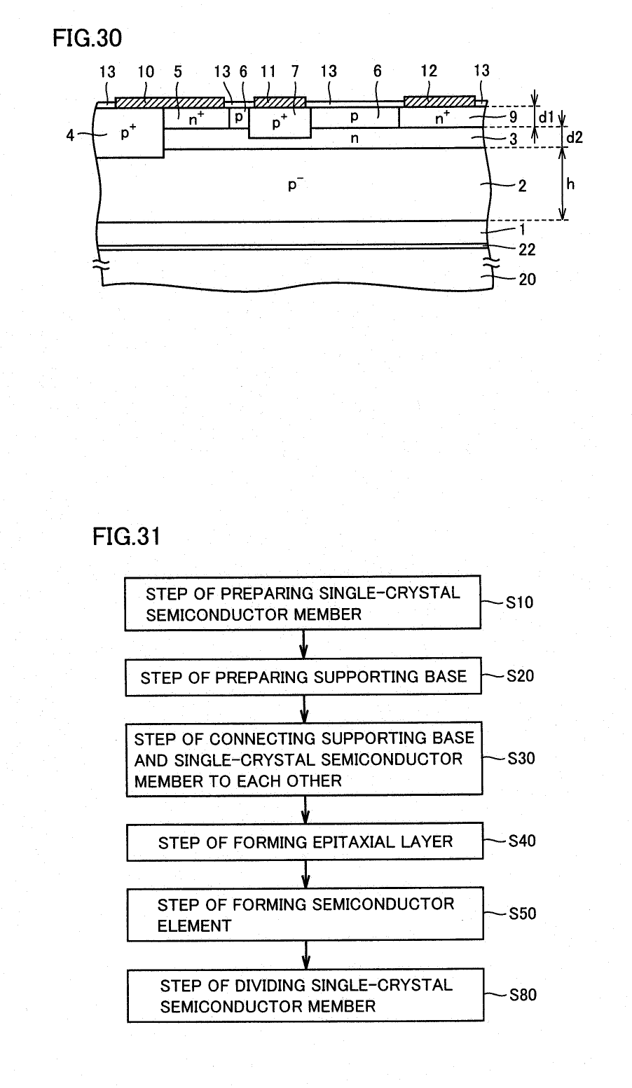

Referring to FIG. 30 and FIG. 31, a fifth embodiment of the semiconductor device and the method for manufacturing the semiconductor device according to the present invention will be described. FIG. 31 is a flowchart for illustrating a method for manufacturing a semiconductor device shown in FIG. 30.

Referring to FIG. 30, a semiconductor device according to the present invention is a lateral type JFET and is formed using a combined substrate according to the present invention. Specifically, as the semiconductor substrate, there is used a combined substrate constituted by a supporting base 20, a connecting layer 22, and a SiC single-crystal substrate 1. SiC single-crystal substrate 1 may have any conductivity type. On SiC single-crystal substrate 1, as shown in FIG. 30, a p⁻ type epitaxial layer 2 is formed. P⁻ type epitaxial layer 2 contains an impurity of first conductivity type, serves as a first semiconductor layer, and has a thickness h. On this p⁻ type epitaxial layer 2, an n type epitaxial layer 3 is formed. N type epitaxial layer 3 contains an impurity of second conductivity type at an impurity concentration higher than that in p⁻ type epitaxial layer 2, serves as a second semiconductor layer, and has a thickness d2. On this n type epitaxial layer 3, a p type epitaxial layer 6 serving as a third semiconductor layer is formed.

This p type epitaxial layer 6 is provided with an n⁺ type source region layer 5 and an n⁺ type drain region layer 9. N⁺ type source region layer 5 and n⁺ type drain region layer 9 are disposed with a predetermined space interposed therebetween, contain an impurity of second conductivity type at an impurity concentration higher than that in n type epitaxial layer 3, and have a thickness d1. Further, between source region layer 5 and drain region layer 9, a p⁺ type gate region layer 7 is formed. P⁺ type gate region layer 7 has a lower surface coming into n type epitaxial layer 3 and contains an impurity of first conductivity type at an impurity concentration higher than that in n type epitaxial layer 3.

On the surfaces of n⁺ type source region layer 5, n⁺ type drain region layer 9, and p⁺ type gate region layer 7, a source electrode 10, a gate electrode 11, and a drain electrode 12 are provided respectively. It should be noted that a p⁺ type semiconductor layer 4 is formed next to source region layer 5, so as to come into p⁻ type epitaxial layer 2.

Next, a method for manufacturing the semiconductor device shown in FIG. 30 will be described with reference to FIG. 31. As shown in FIG. 31, step (S10) of preparing the single-crystal semiconductor member, step (S20) of preparing the supporting base, step (S30) of connecting the supporting base and the single-crystal semiconductor member to each other, step (S40) of forming the epitaxial layer, and step (S50) of forming the semiconductor element are performed. These step (S10) to step (S50) are basically the same as those in the method for manufacturing the semiconductor device in the first embodiment or the second embodiment of the present invention, correspondingly.

Thereafter, in the present embodiment, SiC single-crystal substrate 1 is not separated from supporting base 20 before performing step (S80) of dividing the single-crystal semiconductor member. In this step (S80), not only SiC single-crystal substrate 1 but also connecting layer 22 and supporting base 20 are divided together. As a result, the semiconductor device shown in FIG. 30 can be obtained.

In each of the above-described embodiments, it has been illustrated that SiC single-crystal substrate 1 is an example of the single-crystal semiconductor member, but instead of SiC single-crystal substrate 1, another compound semiconductor substrate such as a nitride semiconductor substrate (for example, gallium nitride (GaN) substrate or the like) may be used.

### Example 1

The following describes a method for manufacturing a semiconductor device as an example corresponding to the above-described first embodiment. First, a 2-inch silicon carbide single-crystal ingot grown by means of a sublimation method is sliced to obtain a substrate that is to serve as SiC single-crystal substrate 1 and has a thickness of 100 μm. One main surface (one surface) of the substrate is mechanically polished for mirror finish. Then, a TiAlSi film is formed on the mirror-finished surface thereof by means of the sputtering method.

Next, a silicon carbide polycrystal substrate is processed to have a thickness of approximately 400 μm by means of grinding. Then, one surface of this substrate is mechanically polished for mirror finish, thereby preparing a first supporting base. A resist is applied to the mirror-finished surface of the first supporting base. Then, the surface of the SiC single-crystal substrate on which the TiAlSi film is formed is adhered onto the resist-applied surface of the first supporting base. In this state, the resist is solidified by means of heat treatment at a heating temperature of 100° C. Further, in a vacuum furnace, while applying a load of 500 g weight to press the first supporting base and the SiC single-crystal substrate against each other at a pressure of 10⁻³ Torr or smaller, heat treatment is performed at a heating temperature of 800° C., thereby forming the resist into connecting layer 22 containing carbon as its main component. As a result, connecting layer 22 thus formed allows the SiC single-crystal substrate and the supporting base to be connected to each other.

With the SiC single-crystal substrate and the supporting base combined with each other as above, the SiC single-crystal substrate is lapped and polished to be thinned to a thickness of 50 μm. Finally, final polishing is performed to the SiC single-crystal substrate using colloidal silica by means of a chemical mechanical polishing (CMP) method. In this way, a combined substrate according to the present invention can be obtained.

Next, on the surface of the SiC single-crystal substrate of the combined substrate, an epitaxial layer is formed using a CVD device to have a thickness of 10 μm and a carrier concentration of 1×10¹⁶ cm⁻³. Epitaxial growth conditions therefor are as follows: the substrate temperature is set at 1550° C.; the flow rate of hydrogen of gases utilized is set at 150 SLM; the flow rate of SiH₄ is set at 50 sccm; the flow rate of C₂H₆ is set at 50 sccm; the flow rate of nitrogen of 2 ppm is set at 6 sccm; and growth time is set at 90 minutes.

Next, aluminum (Al) ions are implanted into the epitaxial layer by means of the ion implantation method and activation annealing is performed to form a guard ring. Next, a Schottky electrode of 2.4 mm□ is formed by performing vacuum deposition of titanium (Ti) on the entire surface of the epitaxial layer, then forming a mask pattern thereon by means of the photolithography method, and performing etching. After Schottky annealing of 500° C., a passivation film of SiO₂ is formed. Then, an opening is formed at a region of the passivation film on the Schottky electrode. Then, an electrode pad made of Al/Si is formed to make contact with the Schottky electrode in the opening and to extend onto the passivation film.

Next, the surface thus having the electrode pad formed thereon is fixed to a second supporting base using a heat-resistant tape. Then, the combined substrate having the second supporting base thus fixed thereto is placed in oxygen plasma to decompose and remove the connecting layer, thereby detaching the first supporting base from the SiC single-crystal substrate. Then, the surface of the TiAlSi film from which the connecting layer has been removed is subjected to sputtering using argon plasma so as to clean the surface. Thereafter, the second supporting base is removed from the SiC single-crystal substrate.

Finally, the SiC single-crystal substrate thus having the Schottky barrier diodes (SBDs) formed thereon is diced, thereby forming the SDBs into chips. In this way, the SBDs can be obtained as the semiconductor devices according to the present invention. Further, the first supporting base can be reused by connecting and fixing it to another SiC single-crystal substrate again.

### Example 2

The following describes a method for manufacturing a semiconductor device as an example corresponding to the above-described second embodiment. First, a silicon carbide single-crystal ingot grown by the sublimation method is shaped and is cut to obtain SiC single-crystal substrates, each of which is a rectangular single-crystal material having a longitudinal side of 20 mm, a lateral side of 40 mm, and a thickness of 100 μm. One surface of each of the SiC single-crystal substrates is mechanically polished for mirror finishing. On the mirror-finished surface (backside surface), a TiAlSi film is formed by means of the sputtering.

Next, as a first supporting base, there is separately prepared a silicon carbide polycrystal plate of a square having longitudinal and lateral sides of 150 mm. One main surface of this first supporting base is mechanically polished for mirror finishing. A resist is applied to the mirror-finished surface of the first supporting base. Then, the SiC single-crystal substrate is adhered to the first supporting base with its polished surface (surface having the TAlSi film formed thereon) meeting the first supporting base. Then, they are thermally treated at a heating temperature of 100° C. to solidify the resist. In this way, the combined substrate shown in FIG. 12 in the present invention is obtained. It should be noted that the plurality of SiC single-crystal substrates are disposed on the surface of the supporting base in the form of a matrix of 3 rows×7 columns.

Next, an epitaxial layer is formed using the CVD device on the surface of the SiC single-crystal substrate of the combined substrate, so as to have a thickness of 10 μm and a carrier concentration of 1×10¹⁶ cm⁻³. Epitaxial growth conditions therefor are as follows: the substrate temperature is set at 1550° C.; the flow rate of hydrogen of utilized gases is set at 150 SLM; the flow rate of SiH₄ is set at 50 sccm; the flow rate of C₂H₆ is set at 50 sccm; the flow rate of nitrogen of 2 ppm is set at 6 sccm; and the growth time is set at 90 minutes. By this step, the epitaxial layer (SiC) covers a boundary portion (i.e., the surface of the connecting layer) between the SiC single-crystal substrate and the first supporting base combined together.

Next, using as a mask a SiO₂ layer having an opening pattern, ions of phosphorus (P) are implanted into the epitaxial layer to form an n⁺ type source portion of a transistor. Next, by means of self-alignment using as a mask a W layer formed on the epitaxial layer, Al ions are implanted into a p type body portion. Finally, Al ions are implanted to form a p⁺ region in the source portion and a guard ring. Thereafter, activation annealing for the implanted ions is performed.

Next, by means of sacrificial oxidation, the outermost surface layer of the epitaxial layer is removed. Then, a gate oxide film is formed by means of thermal oxidation. On this gate oxide film, a gate electrode made of polysilicon is formed. Further, a source electrode made of TiAlSi is formed. Thereafter, an interlayer insulating film made of SiO₂ and having a barrier layer made of SiN is formed. Then, on the interlayer insulating film, an upper wire of a stacked structure of Al/Si is formed. A protective film is formed to cover the upper wire.

Next, dry etching is performed to remove a portion of silicon carbide (epitaxial layer) covering the end portion of the interface between the supporting base and the SiC single-crystal substrate combined with each other (more specifically, from the surface of the connecting layer located at this end portion). Then, the surface having the protective film formed thereon is fixed to the second supporting base using a heat-resistant tape. Then, the combined substrate having the second supporting base thus fixed is placed in oxygen plasma to decompose and remove the connecting layer from the portion exposed by the dry etching, thereby detaching the first supporting base from the SiC single-crystal substrate.

Then, the surface of the TiAlSi film from which the connecting layer has been removed is subjected to sputtering using argon plasma so as to clean the surface. Thereafter, the second supporting base is removed from the SiC single-crystal substrate. Finally, the SiC single-crystal substrate is diced into chips. The first supporting base can be reused.

### Example 3

The following describes a method for manufacturing a semiconductor device as an example corresponding to the above-described third embodiment. First, a silicon carbide single-crystal ingot grown by the sublimation method is shaped and cut to obtain SiC single-crystal substrates, each of which is a rectangular single-crystal material having a longitudinal side of 20 mm, a lateral side of 40 mm, and a thickness of 100 μm. The surface of each of the SiC single-crystal carbide substrates thus obtained by the cutting has a surface corresponding to a {03-38} plane, which is inclined by 54.7° relative to the (0001) plane.

Next, as a first supporting base, a sintered compact SiC substrate is separately prepared to have a diameter of 6 inches and a thickness of 600 μm. The SiC substrate is formed to have a multiplicity of holes (i.e., it can be said that the SiC substrate employed here is a porous body). Further, the SiC substrate is provided with openings 41 and stepped portions 42 each located at a location in which the SiC single-crystal substrate is to be installed and each having a depth of 70 μm to allow the SiC single-crystal substrate to be fixed therein (see FIG. 21). Into each of stepped portions 42, the SiC single-crystal substrate having the rectangular shape is to be fit. Nine stepped portions 42 and nine openings 41 are formed in the form of a matrix.

The SiC single-crystal substrate is adhered to stepped portion 42 using a photoresist as shown in FIG. 22. Thereafter, the photoresist is carbonized by performing heating treatment in a nitrogen atmosphere at a heating temperature of 600° C., thereby forming connecting layer 22 (see FIG. 22) containing carbon (containing carbon as its main component). Connecting layer 22 thus formed allows the SiC single-crystal substrate to be connected to the supporting base.

Next, with the SiC single-crystal substrate thus combined with the supporting base, the unpolished surface of the SiC single-crystal substrate is lapped and polished by grinding and mechanical polishing until it comes level with the surface of the supporting base. Finally, final polishing is performed to the polished surface thereof using colloidal silica by means of the chemical mechanical polishing (CMP) method. As a result, the structure shown in FIG. 23 is obtained.

Next, on the surface of the SiC single-crystal substrate of the combined substrate, an epitaxial layer is formed using a CVD device to have a thickness of 12 μm and a carrier concentration of 8×10¹⁵ cm⁻³. Epitaxial growth conditions therefor are as follows: the substrate temperature is set at 1550° C.; the flow rate of hydrogen of gases utilized is set at 150 SLM; the flow rate of SiH₄ is set at 50 sccm; the flow rate of C₂H₆ is set at 50 sccm; the flow rate of nitrogen of 2 ppm is set at 5 sccm; and growth time is set at 90 minutes. By this step, the epitaxial layer (SiC) covers a boundary portion (i.e., the surface of the connecting layer exposed in the outer circumference of stepped portion 42) between the SiC single-crystal substrate and the first supporting base combined with each other.

Next, as with example 2, using as a mask a SiO₂ layer having an opening pattern, ions of phosphorus (P) are implanted into the epitaxial layer to form an n⁺ type source portion of a transistor. Next, by means of self-alignment using as a mask the SiO₂ layer formed on the epitaxial layer, Al ions are implanted into a p type body portion. Finally, Al ions are implanted to form a p⁺ region in the source portion and a guard ring. Thereafter, activation annealing for the implanted ions is performed.

Next, by means of sacrificial oxidation, the outermost surface layer of the epitaxial layer is removed. Then, a gate oxide film is formed by means of thermal oxidation. On this gate oxide film, a gate electrode made of polysilicon is formed. Further, a source electrode made of TiAlSi is formed. Thereafter, a drain electrode made of TiAlSi is formed on the backside surface of the SiC single-crystal substrate, using opening 41 of the supporting base. Thereafter, heat treatment for alloying is performed.

Next, an interlayer insulating film is formed which is made of SiO₂ and has a barrier layer made of SiN. Then, on the interlayer insulating film, an upper wire of a stacked structure of Al/Si is formed. A protective film is formed to cover the upper wire.

Next, dry etching is performed to remove a portion of silicon carbide (epitaxial layer) covering the end portion of the interface between the supporting base and the SiC single-crystal substrate combined with each other (more specifically, the outer circumferential end portion of stepped portion 42). Thereafter, the surface having the protective, film formed thereon is fixed to the second supporting base using a heat-resistant tape. Further, the above-described sacrificial oxidation step also serves as the step of removing the carbide originating from the resist and serving as the connecting layer (in other words, the connecting layer is oxidized and removed from the opening 41 side by the sacrificial oxidation step). Hence, with the SiC single-crystal substrate being fixed to the second supporting base, the SiC single-crystal substrate and the second supporting base can be separated from the first supporting base. Finally, the SiC single-crystal substrate is diced into chips. The first supporting base can be reused.

It should be noted that as described above, just before the step of removing the first supporting base from the SiC single-crystal substrate, the first supporting base has a thickness of approximately 70 μm. Hence, without removing the first supporting base from the SiC single-crystal substrate, the SiC single-crystal substrate and the first supporting base can be formed into chips readily (using for example laser).

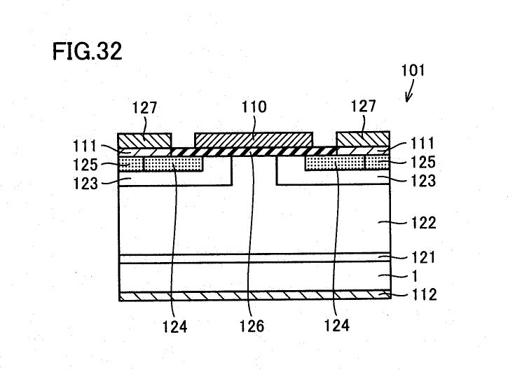

Further, in the method for manufacturing the semiconductor device as illustrated in the above-described first to fourth embodiments of the present invention, a vertical type device can be formed as shown in FIG. 32. Here, the following describes another exemplary semiconductor device fabricated using a SiC single-crystal substrate of the present invention (single-crystal substrate made of silicon carbide). Referring to FIG. 32, a semiconductor device 101 according to the present invention is a DiMOSFET (Double Implanted MOSFET) of vertical type, and has a single-crystal substrate 1, a buffer layer 121, a breakdown voltage holding layer 122, p regions 123, n⁺ regions 124, p⁺ regions 125, an oxide film 126, source electrodes 111, upper source electrodes 127, a gate electrode 110, and a drain electrode 112 formed on the backside surface of single-crystal substrate 1. Specifically, buffer layer 121 made of silicon carbide is formed on the front-side surface of single-crystal substrate 1 made of silicon carbide of n type conductivity. As single-crystal substrate 1, there is employed a silicon carbide substrate of the present invention inclusive of single-crystal substrate 1 illustrated in the first to fourth embodiments described above. In the case where single-crystal substrate 1 in each of the first to fourth embodiments is employed, buffer layer 121 is formed on the main surface of single-crystal substrate 1. Buffer layer 121 has n type conductivity, and has a thickness of, for example, 0.5 μm. Further, impurity with n type conductivity in buffer layer 121 has a concentration of, for example, 5×10¹⁷ cm⁻³. Formed on buffer layer 121 is breakdown voltage holding layer 122. Breakdown voltage holding layer 122 is made of silicon carbide of n type conductivity, and has a thickness of 10 μm, for example. Further, breakdown voltage holding layer 122 includes an impurity of n type conductivity at a concentration of, for example, 5×10¹⁵ cm⁻³.

Breakdown voltage holding layer 122 has a surface in which p regions 123 of p type conductivity are formed with a space therebetween. In each of p regions 123, an n⁺ region 124 is formed at the surface layer of p region 123. Further, at a location adjacent to n⁺ region 124, a p⁺ region 125 is formed. Oxide film 126 is formed to extend on n⁺ region 124 in one p region 123, p region 123, an exposed portion of breakdown voltage holding layer 122 between the two p regions 123, the other p region 123, and n⁺ region 124 in the other p region 123. On oxide film 126, gate electrode 110 is formed. Further, source electrodes 111 are formed on n⁺ regions 124 and p⁺ regions 125. On source electrodes 111, upper source electrodes 127 are formed. Moreover, drain electrode 112 is formed on the backside surface of substrate 102, i.e., the surface opposite to its front-side surface on which buffer layer 121 is formed.

In semiconductor device 101 shown in FIG. 32, the silicon carbide substrate of the present invention can be employed as single-crystal substrate 1, such as single-crystal substrate 1 illustrated in each of the first to fourth embodiments. Namely, semiconductor device 101 includes: single-crystal substrate 1 serving as the silicon carbide substrate; buffer layer 121 and breakdown voltage holding layer 122 both serving as the epitaxial growth layer formed on single-crystal substrate 1; and source electrodes 111 formed on breakdown voltage holding layer 122. Further, single-crystal substrate 1 is the silicon carbide substrate of the present invention. Here, the silicon carbide substrate of the present invention is connected to supporting base 20 (for example, see FIG. 4, FIG. 13, or the like) in the step of forming the epitaxial layer or the like. Hence, the thickness thereof can be sufficiently thin. Hence, semiconductor device 101 is manufactured to have reduced on-resistance.

The following describes a method for manufacturing semiconductor device 101 shown in FIG. 32. First, step (S10) of preparing the single-crystal semiconductor member as shown in FIG. 1 or the like is performed. Prepared here is, for example, single-crystal substrate 1, which is made of silicon carbide and has its main surface corresponding to the (03-38) plane (see FIG. 2, for example). As single-crystal substrate 1, there is prepared a silicon carbide substrate of the present invention, inclusive of silicon carbide substrate 1 described in each of the first to fourth embodiments.

As this single-crystal substrate 1, a substrate may be employed which has n type conductivity and has a substrate resistance of 0.02 Ωcm.

Next, for example, after performing step (S20) and step (S30) shown in FIG. 1, step (S40) of forming the epitaxial layer is performed. Specifically, buffer layer 121 is formed on the surface of single-crystal substrate 1. Buffer layer 121 is formed on the main surface of single-crystal substrate 1. As buffer layer 121, an epitaxial layer is formed which is made of silicon carbide of n type conductivity and has a thickness of 0.5 μm, for example. Buffer layer 121 has a conductive impurity at a concentration of, for example, 5×10¹⁷ cm⁻³. Then, on buffer layer 121, breakdown voltage holding layer 122 is formed. As breakdown voltage holding layer 122, a layer made of silicon carbide of n type conductivity is formed using the epitaxial growth method. Breakdown voltage holding layer 122 can have a thickness of, for example, 10 μm. Further, breakdown voltage holding layer 122 includes an impurity of n type conductivity at a concentration of, for example, 5×10¹⁵ cm⁻³.

Next, step (S60) of forming the semiconductor element as shown in FIG. 1 is performed. Specifically, first, an implantation step is performed. More specifically, an impurity of p type conductivity is implanted into breakdown voltage holding layer 122 using, as a mask, an oxide film formed through photolithography and etching, thereby forming p regions 123. Further, after removing the oxide film thus used, an oxide film having a new pattern is formed through photolithography and etching. Using this oxide film as a mask, a conductive impurity of n type conductivity is implanted into predetermined regions to form n⁺ regions 124. In a similar way, a conductive impurity of p type conductivity is implanted to form p⁺ regions 125.

After such an implantation step, an activation annealing process is performed. This activation annealing process can be performed under conditions that, for example, argon gas is employed as atmospheric gas, heating temperature is set at 1700° C., and heating time is set at 30 minutes.

Next, a gate insulating film forming step is performed. Specifically, oxide film 126 is formed to cover breakdown voltage holding layer 122, p regions 123, n⁺ regions 124, and p⁺ regions 125. As a condition for forming oxide film 126, for example, dry oxidation (thermal oxidation) may be performed. The dry oxidation can be performed under conditions that the heating temperature is set at 1200° C. and the heating time is set at 30 minutes.

Thereafter, a nitrogen annealing step (S150) is performed. Specifically, an annealing process is performed in atmospheric gas of nitrogen monoxide (NO). Temperature conditions for this annealing process are, for example, as follows: the heating temperature is 1100° C. and the heating time is 120 minutes. As a result, nitrogen atoms are introduced into a vicinity of the interface between oxide film 126 and each of breakdown voltage holding layer 122, p regions 123, n⁺ regions 124, and p⁺ regions 125, which are disposed below oxide film 126. Further, after the annealing step using the atmospheric gas of nitrogen monoxide, additional annealing may be performed using argon (Ar) gas, which is an inert gas. Specifically, using the atmospheric gas of argon gas, the additional annealing may be performed under conditions that the heating temperature is set at 1100° C. and the heating time is set at 60 minutes.

Next, the electrode forming step is performed. Specifically, a resist film having a pattern is formed on oxide film 126 by means of the photolithography method. Using the resist film as a mask, portions of the oxide film above n⁺ regions 124 and p⁺ regions 125 are removed by etching. Thereafter, a conductive film such as a metal is formed on the resist film and formed in openings of oxide film 126 in contact with n⁺ regions 124 and p⁺ regions 125. Thereafter, the resist film is removed, thus removing the conductive film's portions located on the resist film (lift-off). Here, as the conductor, nickel (Ni) can be used, for example. As a result, source electrodes 111 can be obtained. It should be noted that on this occasion, heat treatment for alloying is preferably performed. Specifically, using atmospheric gas of argon (Ar) gas, which is an inert gas, the heat treatment (alloying treatment) is performed with the heating temperature being set at 950° C. and the heating time being set at 2 minutes. Thereafter, on source electrodes 111, upper source electrodes 127 are formed. Further, gate electrode 110 is formed on oxide film 126.

Then, step (S60) of FIG. 1 is performed, and thereafter step (S70) is performed. Specifically, drain electrode 112 is formed on the backside surface of single-crystal substrate 1. In this way, semiconductor device 101 shown in FIG. 32 can be obtained. In other words, semiconductor device 101 is fabricated by forming the epitaxial layer and the electrodes on the main surface of single-crystal substrate 1.

Further, in the above-described semiconductor device, it has been illustrated that the semiconductor device is fabricated by forming the epitaxial layer, which serves as an active layer, on the silicon carbide substrate having its main surface corresponding to the (03-38) plane. However, the crystal plane that can be adopted for the main surface is not limited to this and any crystal plane suitable for the purpose of use and including the (0001) plane can be adopted for the main surface.

The following describes characteristic configurations of the present invention, although some of them have been already described in the embodiments or examples described above.

A method for manufacturing a semiconductor element 30 serving as a semiconductor device according to the present invention includes: a step (S10) of preparing a single-crystal semiconductor member (for example, a SiC single-crystal substrate 1); a step (S20) of preparing a supporting base 20; a step (S30) of connecting supporting base 20 and the single-crystal semiconductor member (SiC single-crystal substrate 1) to each other through a connecting layer 22 containing carbon; a step (S40) of forming an epitaxial layer 23 on a surface of SiC single-crystal substrate 1; a step (S50) of forming the semiconductor element using epitaxial layer 23; a step (S60) of separating SiC single-crystal substrate 1 from supporting base 20 by oxidizing and accordingly decomposing connecting layer 22 after step (S50) of forming the semiconductor element; and a step (S80) of dividing SiC single-crystal substrate 1 separated from supporting base 20.

In this case, step (S50) of forming the semiconductor element can be performed using combined substrate 21 in which SiC single-crystal substrate 1 is connected to supporting base 20. Hence, in step (S50), SiC single-crystal substrate 1 can be handled more readily. Further, the process in step (S50) of forming the semiconductor element is performed with SiC single-crystal substrate 1 being connected to supporting base 20. Hence, SiC single-crystal substrate 1 does not need to necessarily secure a thickness with which SiC single-crystal substrate 1 can stand by itself. The thickness thereof can be determined in view of characteristics (such as on-resistance) of a final product of the semiconductor element (element 30). Thus, in order to reduce the on-resistance for example, the thickness of SiC single-crystal substrate 1 can be set at a thickness smaller than the lower limit of a thickness with which SiC single-crystal substrate 1 can stand by itself. As a result, there can be realized a semiconductor device having excellent characteristics (for example, sufficiently low on-resistance).

Further, because connecting layer 22 for connecting SiC single-crystal substrate 1 to supporting base 20 contains carbon, connecting layer 22 can be readily decomposed when being oxidized. Accordingly, SiC single-crystal substrate 1 can be readily separated from supporting base 20 after forming the semiconductor element (element 30) on SiC single-crystal substrate 1.

Further, connecting layer 22 containing carbon is preferably a connecting layer containing carbon as its main component. For example, as connecting layer 22, there can be used a layer obtained by thermally treating (carbonizing) a photoresist or a resin to solidify it into carbon of a substantially solid. Connecting layer 22 thus containing carbon as its main component can sufficiently maintain the connection between SiC single-crystal substrate 1 and supporting base 20 even at a heat treatment temperature (for example, approximately 1000° C.) in step (S50) of forming the semiconductor element, as long as connecting layer 22 is not exposed to oxidizing atmosphere.

Examples of a material formed into connecting layer 22 by the heat treatment include phenol resin, glucose, and the like in addition to the photoresist described above. The material formed into connecting layer 22 by the heat treatment may be a liquid-state material such as the above-described photoresist but may be, for example, a gel material having a high viscosity or a solid-state material such as a material of a tape-like shape or a film-like shape. In the case of using such a solid-state material, the material preferably has adhesiveness. Further, the heat treatment for forming connecting layer 22 is preferably of carbonizing a layer that is to be formed into connecting layer 22 (for example, a layer containing carbon as its main component). The heat treatment can be performed, for example, in vacuum or inert gas atmosphere at a heating temperature of 500° C. or greater, preferably, 700° C. or greater for a predetermined time (for example, not less than 30 minutes and not more than 90 minutes).

The method for manufacturing the semiconductor device may include a step (S40) of forming a protective film (epitaxial layer 23 formed to cover the exposed surface of connecting layer 22) to cover the exposed surface of connecting layer 22 (for example, the step of forming epitaxial layer 23 as illustrated in FIG. 12 and FIG. 13) after step (S30) of connecting and before step (S50) of forming the semiconductor element. Further, the method for manufacturing the semiconductor device may include a step of removing the protective film (for example, the step of removing epitaxial layer 23 from the vicinity of the connection portion between SiC single-crystal substrate 1 and supporting base 20 as illustrated in FIG. 14) after step (S50) of forming the semiconductor element and before step (S60) of separating. For the protective film, it is preferable to use a material having a higher resistance to oxidizing atmosphere than that of connecting layer 22. For example, the protective film is preferably formed of an oxidation-resistant material. For example, as the protective film, the above-described SiC epitaxial film can be employed. Examples of other materials usable therefor include silicon oxide (such as SiO₂), silicon nitride (SiN), aluminum oxide (Al₂O₃), and the like. Further, the protective film may be formed simultaneously with the formation of the epitaxial film on SiC single-crystal substrate 1 as illustrated in the above-described second embodiment or the like, but an independent step of forming the protective film may be performed. For example, there may be performed a step of forming a mask layer having an opening pattern for exposing only the surface of connecting layer 22 so as to form a film that is to serve as the protective film.

In this case, the protective film thus existing prevents connecting layer 22 from being directly exposed to the treatment atmosphere in step (S50) of forming the semiconductor element. Accordingly, connecting layer 22 can be prevented from being damaged even when using atmosphere that could have decomposed connecting layer 22 in step (S50) of forming the semiconductor element. Further, before the step of separating, the protective film is removed. Hence, connecting layer 22 can be securely decomposed and removed in step (S60) of separating.

In the method for manufacturing the semiconductor device, step (S50) of forming the semiconductor element may include a step of applying a photoresist onto epitaxial layer 23. In the step of applying the photoresist, one of a roller application method and a nozzle jetting application method may be employed.

Here, assume that a plurality of SiC single-crystal substrates 1 are connected to supporting base 20 through connecting layer 22 as in the second embodiment to the fifth embodiment. On this occasion, even when a gap is formed between the plurality of SiC single-crystal substrates 1 on supporting base 20, the above-described roller application method or the nozzle jetting application method allows the photoresist to be disposed more securely and uniformly on the epitaxial layer formed on the upper surface (main surface) of SiC single-crystal substrates 1, as compared with a case of using a spin coating method. This prevents deterioration in precision of the shape of a pattern formed using the photoresist by means of the photolithography method, with the result that defect of elements 30 can be restrained from being produced due to the deterioration in the precision of the shape. This restrains manufacturing yield of the semiconductor devices (elements 30) from being reduced.

In step (S60) of separating in the method for manufacturing the semiconductor device, supporting base 20 from which SiC single-crystal substrate 1 has been removed may be reused as the supporting base prepared in step (S20) of preparing the supporting base. Because supporting base 20 can be reused in this case, manufacturing cost of the semiconductor devices can be reduced as compared with a case where supporting base 20 is thrown away after being used once.

A method for manufacturing a combined substrate according to the present invention includes a step (S10) of preparing a single-crystal semiconductor member (SiC single-crystal substrate 1); a step (S20) of preparing a supporting base 20; and a step (S30) of connecting supporting base 20 and SiC single-crystal substrate 1 to each other through a connecting layer 22 containing carbon.

In this way, because supporting base 20 is connected to SiC single-crystal substrate 1, combined substrate 21 can be handled well even when the thickness of SiC single-crystal substrate 1 is thin. Further, the process of forming a semiconductor element (element 30) on the SiC single-crystal substrate of combined substrate 21 is performed with SiC single-crystal substrate 1 being connected to supporting base 20. Hence, SiC single-crystal substrate 1 does not need to necessarily secure a thickness with which SiC single-crystal substrate 1 can stand by itself. The thickness of SiC single-crystal substrate 1 can be determined in view of characteristics (such as on-resistance) of a final product of the semiconductor element (element 30). Thus, in order to reduce the on-resistance for example, the thickness of SiC single-crystal substrate 1 can be set at a thickness smaller than the lower limit of a thickness with which SiC single-crystal substrate 1 can stand by itself. As a result, according to the present invention, there can be obtained combined substrate 21 by which a semiconductor device having excellent characteristics (for example, sufficiently low on-resistance) can be manufactured.

Further, connecting layer 22 for connecting the single-crystal semiconductor member such as SiC single-crystal substrate 1 to supporting base 20 contains carbon. Hence, connecting layer 22 can be readily decomposed when being oxidized. Accordingly, SiC single-crystal substrate 1 and the like can be readily separated from supporting base 20.

In the method for manufacturing the semiconductor device or the method for manufacturing the combined substrate, the single-crystal semiconductor member (SiC single-crystal substrate 1) may have a thickness of not more than 100 μm and SiC single-crystal substrate 1 may have a carrier concentration of not less than 1×10¹⁸ cm⁻³. Preferably, the thickness of SiC single-crystal substrate 1 is not more than 50 μm. In this case, it is considered that when forming a semiconductor element on SiC single-crystal substrate 1, the above-described carrier concentration results in decreased mobility (for example, 100 cmV/s) in SiC single-crystal substrate 1. However, by defining the thickness of SiC single-crystal substrate 1 as above, electric resistance can be maintained sufficiently low (for example, 0.5 mΩcm² or smaller) in the thickness direction of SiC single-crystal substrate 1. Hence, with the method for manufacturing the semiconductor device using combined substrate 21, there can be realized a semiconductor device allowing for sufficiently low electric resistance in the longitudinal direction thereof and accordingly achieving sufficiently reduced loss.

The method for manufacturing the combined substrate may further include a step of forming a protective film to cover an exposed surface of connecting layer 22 as shown in FIG. 13 (epitaxial layer 23 formed on a boundary portion between the lower portion of the end surface of SiC single-crystal substrate 1 and the upper surface of supporting base 20). For the protective film (epitaxial layer 23 of SiC), it is preferable to use a material having a higher resistance to oxidizing atmosphere than that of connecting layer 22. For example, the protective film is preferably made of an oxidation-resistant material. In this case, the protective film thus formed prevents connecting layer 22 from being directly exposed to the treatment atmosphere when forming the semiconductor device using combined substrate 21. Accordingly, connecting layer 22 can be prevented from being damaged even when using atmosphere (such as oxidizing atmosphere) that could have decomposed connecting layer 22 in the step of forming the semiconductor device.

In the method for manufacturing the semiconductor device or the method for manufacturing the combined substrate, the protective film may be made of a material containing at least one selected from a group consisting of silicon carbide (SiC), silicon oxide, silicon nitride, and aluminum oxide (Al₂O₃). In this case, each of the materials described above is an oxidation-resistant material that withstands a relatively high temperature (for example approximately 1000° C.) and exhibits sufficient durability when forming a semiconductor device using combined substrate 21. Hence, connecting layer 22 can be securely protected.

Further, as described above in the second embodiment, the protective film may be made of the same material (SiC) as the material constituting the single-crystal semiconductor member (SiC single-crystal substrate 1). For example, when using silicon carbide (SiC) for the material constituting the single-crystal semiconductor member as described above, silicon carbide can be also used for the protective film. In this case, in the process for manufacturing the semiconductor device, the protective film made of silicon carbide can be formed simultaneously when forming the epitaxial layer made of silicon carbide on the surface of the single-crystal semiconductor member (SiC single-crystal substrate 1) in step (S40). Hence, an additional step for only forming the protective film does not need to be performed apart from step (S40) of forming the epitaxial layer. Thus, the number of steps in manufacturing can be restrained from increasing when manufacturing the semiconductor device.

In the method for manufacturing the semiconductor device or the method for manufacturing the combined substrate, step (S10) of preparing the single-crystal semiconductor member may include a step (step (S70) of FIG. 27) of forming a metal layer (conductor layer to serve as backside electrode 26) on the single-crystal semiconductor member (SiC single-crystal substrate 1) at its surface to be connected to supporting base 20 through connecting layer 22.

In this case, the metal layer (metal layer to serve as backside electrode 26 as shown in FIG. 28 and FIG. 29) is formed in advance on the surface (backside surface) of SiC single-crystal substrate 1 to be connected to supporting base 20. Accordingly, when performing the method for manufacturing the semiconductor device using combined substrate 21, an ohmic junction is formed, by heat treatment in the method for manufacturing, at a portion at which SiC single-crystal substrate 1 and the metal layer are brought into contact with each other. Hence, in the semiconductor device formed using combined substrate 21, the metal layer can be used as backside electrode 26.

Further, in the case of manufacturing the semiconductor device using combined substrate 21, additional heat treatment for forming the ohmic junction does not need to be performed after forming the metal layer that is to be formed into the electrode, unlike the case where a device structure is formed on SiC single-crystal substrate 1, thereafter supporting base 20 is removed from SiC single-crystal substrate 1, and then the electrode (backside electrode 26) is formed on the backside surface thereof. (Even if additional heat treatment is required, a treatment temperature for the heat treatment can be reduced).

In the method for manufacturing the semiconductor device or the method for manufacturing the combined substrate, in step (S10) of preparing the single-crystal semiconductor member, a plurality of the single-crystal semiconductor members (SiC single-crystal substrates 1) may be prepared as shown in FIG. 10, FIG. 18, and the like. Further, in the method for manufacturing the semiconductor device, in step (S30) of connecting, the plurality of single-crystal semiconductor members (SiC single-crystal substrates 1) may be connected to supporting base 20 through connecting layer 22. In doing so, the plurality of single-crystal semiconductor members (SiC single-crystal substrates 1) may be arranged side by side on the surface of supporting base 20. Further, it is preferable to form a gap between two single-crystal semiconductor members (SiC single-crystal substrates 1) disposed adjacent to each other as shown in FIG. 12 and the like. In this case, through the gap, oxidizing atmosphere such as oxygen plasma surely reaches connecting layer 22 in step (S60) of separating the single-crystal semiconductor member in the method for manufacturing the semiconductor device. Thus, in step (S60) of separating, the single-crystal semiconductor members (SiC single-crystal substrates 1) can be securely separated from supporting base 20.

In the method for manufacturing the semiconductor device or the method for manufacturing the combined substrate, supporting base 20 may have a quadrangular planar shape as illustrated in the above-described second embodiment. Further, the single-crystal semiconductor member (SiC single-crystal substrate 1) preferably also has a quadrangular planar shape. Apart from the circular or quadrangular shape, the planar shape of supporting base 20 may be a polygonal shape such as a triangle or a pentagon. Also, it is preferable to connect the plurality of single-crystal semiconductor members (SiC single-crystal substrates 1) to supporting base 20 through connecting layer 22 as illustrated in the above-described second and third embodiments. Further, the planar shape of supporting base 20 may be analogue to that of the single-crystal semiconductor members (SiC single-crystal substrates 1), or may be a polygon having the same number of angles. In this case, when connecting the plurality of single-crystal semiconductor members (SiC single-crystal substrates 1) to one supporting base 20, the single-crystal semiconductor members (SiC single-crystal substrates 1) to be connected thereto can be arranged to exist even at the corners of the supporting base 20. Accordingly, the number of SiC single-crystal substrates 1 that can be processed at one time can be increased, thus manufacturing semiconductor devices efficiently (or obtaining combined substrate 21 by which semiconductor devices can be manufactured efficiently). Further, a semiconductor device to be manufactured usually has a quadrangular planar shape. Hence, when the planar shapes of supporting base 20 and the single-crystal semiconductor member (SiC single-crystal substrate 1) are quadrangular as described above, the number of semiconductor devices to be obtained from one single-crystal semiconductor member (SiC single-crystal substrate 1) can be increased as compared with that in the case of using a single-crystal semiconductor member (SiC single-crystal substrate 1) having a circular planar shape and having substantially the same area.

In the method for manufacturing the semiconductor device or the method for manufacturing the combined substrate, the single-crystal semiconductor member illustrated as SiC single-crystal substrate 1 may be made of a material containing one of silicon carbide (SiC) and nitride semiconductor. Supporting base 20 may be made of a material containing at least one selected from a group containing silicon carbide (SiC), alumina (Al₂O₃), sapphire, silicon (Si), and silicon nitride. In the case where such materials are used, the connection with connecting layer 22 containing carbon can be maintained even under relatively high temperature environment. In addition, they can withstand a process of high temperature.

In the method for manufacturing the semiconductor device or the method for manufacturing the combined substrate, supporting base 20 may be provided with a through hole (opening 41) capable of receiving the single-crystal semiconductor member (SiC single-crystal substrate 1) therein. In this case, the single-crystal semiconductor member (SiC single-crystal substrate 1) is disposed in opening 41 of supporting base 20 (for example, stepped portion 42 shown in FIG. 22 or FIG. 23). Hence, connecting layer 22 is disposed at the outer circumference of the single-crystal semiconductor member (SiC single-crystal substrate 1) (portion opposite to the inner wall of stepped portion 42 of opening 41). Hence, in step (S60) of separating in the method for manufacturing the semiconductor device, oxidizing atmosphere can readily reach connecting layer 22, thereby securely decomposing connecting layer 22. Thus, in step (S60) of separating, the single-crystal semiconductor member (SiC single-crystal substrate 1) can be securely separated from supporting base 20.

A semiconductor device according to the present invention includes: a supporting base 20; a single-crystal semiconductor layer (a SiC single-crystal substrate 1 and an epitaxial layer formed on the surface of SiC single-crystal substrate 1 and located between SiC single-crystal substrate 1 and a gate electrode 11); and an electrode (a source electrode 10, gate electrode 11, and a drain electrode 12) as illustrated in FIG. 30. The single-crystal semiconductor layer (SiC single-crystal substrate 1 and the epitaxial layer) is connected onto a surface of supporting base 20 through a connecting layer 22 containing carbon. The electrode is formed on the single-crystal semiconductor layer (SiC single-crystal substrate 1 and the epitaxial layer). In this way, supporting base 20 can be used as a reinforcement member. Hence, only a minimum thickness required for operation of the device may be secured for the thickness of the high-quality single-crystal semiconductor layer (in particular, SiC single-crystal substrate 1). Accordingly, the thickness of the single-crystal semiconductor layer can be thinner than that in the case of forming a semiconductor device only using a single-crystal semiconductor layer. As a result, the manufacturing cost of the semiconductor device can be reduced. It should be noted that the single-crystal semiconductor layer may include the single-crystal semiconductor member (SiC single-crystal substrate 1) connected to the surface of supporting base 20 through connecting layer 22, and the epitaxial layer formed on the surface of the single-crystal semiconductor member (SiC single-crystal substrate 1) as described above. Alternatively, the single-crystal semiconductor layer may be constituted only by the single-crystal semiconductor member (SiC single-crystal substrate 1).

In the semiconductor device, supporting base 20 may be formed of a conductive material. In this case, supporting base 20 is conductive. Hence, a ground electrode of the semiconductor device can be formed on the backside surface of the single-crystal semiconductor layer (surface of SiC single-crystal substrate 1 at the supporting base 20 side) (the semiconductor device can be grounded from the backside surface side). It should be noted that connecting layer 22 containing carbon is preferably a connecting layer 22 containing carbon as its main component and having conductivity. Further, the expression “connecting layer 22 containing carbon as its main component” is intended to mean a connecting layer containing carbon at a content of 50% or greater in volume percent.

In the semiconductor device, the single-crystal semiconductor layer (SiC single-crystal substrate 1 and the epitaxial layer) may be made of a material containing one of silicon carbide (SiC) and nitride semiconductor (such as GaN). Further, supporting base 20 may be made of a material containing at least one selected from a group consisting of silicon carbide (SiC), alumina, sapphire, silicon, and silicon nitride. In the case where such materials are used, the connection with the connecting layer containing carbon can be maintained even under relatively high temperature environment. In addition, they can withstand a process of high temperature.

A combined substrate 21 according to the present invention includes a supporting base 20, and a single-crystal semiconductor member (SiC single-crystal substrate 1). The single-crystal semiconductor member (SiC single-crystal substrate 1) is connected onto a surface of supporting base 20 through a connecting layer 22 containing carbon.

In this way, because supporting base 20 is connected to the single-crystal semiconductor member (SiC single-crystal substrate 1), combined substrate 21 can be handled well even when the thickness of the single-crystal semiconductor member (SiC single-crystal substrate 1) is thin. Further, the process of forming a semiconductor element on the single-crystal semiconductor member (SiC single-crystal substrate 1) of combined substrate 21 is performed with the single-crystal semiconductor member (SiC single-crystal substrate 1) being connected to supporting base 20. Hence, the single-crystal semiconductor member (SiC single-crystal substrate 1) does not need to necessarily secure a thickness with which SiC single-crystal substrate 1 can stand by itself. The thickness of the single-crystal semiconductor member (SiC single-crystal substrate 1) can be determined in view of characteristics (such as on-resistance) of a final product of the semiconductor element (element 30). Thus, in order to reduce the on-resistance for example, the thickness of the single-crystal semiconductor member (SiC single-crystal substrate 1) can be set at a thickness smaller than the lower limit of a thickness with which SiC single-crystal substrate 1 can stand by itself. As a result, by using combined substrate 21 according to the present invention, there can be realized a semiconductor device having excellent characteristics (for example, sufficiently low on-resistance).

Further, connecting layer 22 for connecting the single-crystal semiconductor member (SiC single-crystal substrate 1) to supporting base 20 contains carbon. Hence, connecting layer 22 can be readily decomposed when being oxidized. Accordingly, the single-crystal semiconductor member (SiC single-crystal substrate 1) can be readily separated from supporting base 20.

Combined substrate 21 may further include an epitaxial layer (epitaxial layer 23 of FIG. 13, p⁻ type epitaxial layer 2 of FIG. 30, or the like) formed on a surface of the single-crystal semiconductor layer (SiC single-crystal substrate 1). In this case, by forming the epitaxial layer so as to match characteristics of a semiconductor device to be manufactured, combined substrate 21 suitable for manufacturing of the semiconductor device can be realized.

In combined substrate 21, the single-crystal semiconductor member (SiC single-crystal substrate 1) may have a thickness of not more than 100 μm, and the single-crystal semiconductor member (SiC single-crystal substrate 1) may have a carrier concentration of not less than 1×10¹⁸ cm⁻³. Further, the single-crystal semiconductor member (SiC single-crystal substrate 1) preferably has a thickness of 50 μm or smaller. In this case, it is considered that when forming a semiconductor element on the single-crystal semiconductor member (SiC single-crystal substrate 1), the above-described carrier concentration results in decreased mobility (for example, 100 cmV/s) in the single-crystal semiconductor member (SiC single-crystal substrate 1). However, by defining the thickness of the single-crystal semiconductor member (SiC single-crystal substrate 1) as above, electric resistance can be maintained at a sufficiently low value (for example, 0.5 mΩcm² or smaller) in the thickness direction of the single-crystal semiconductor member (SiC single-crystal substrate 1). Thus, by using combined substrate 21, electric resistance can be sufficiently reduced in the longitudinal direction of the semiconductor device, thereby sufficiently reducing loss in the semiconductor device.

Combined substrate 21 may further include a protective film formed to cover an exposed surface of connecting layer 22 (epitaxial layer 23 formed on a boundary portion between the end surface of SiC single-crystal substrate 1 and the surface of supporting base 20 as shown in FIG. 13). In this case, the protective film thus existing prevents connecting layer 22 from being directly exposed to the treatment atmosphere when forming the semiconductor device using combined substrate 21. Accordingly, connecting layer 22 can be prevented from being damaged even when using atmosphere (such as oxidizing atmosphere) that could have decomposed connecting layer 22 in the step of forming the semiconductor device.

In combined substrate 21, the protective film may be made of a material containing at least one selected from a group consisting of silicon carbide (SiC), silicon oxide, silicon nitride, and aluminum oxide. In this case, each of the materials described above is an oxidation-resistant material that withstands a relatively high temperature (for example approximately 1000° C.) and exhibits sufficient durability when forming a semiconductor device using combined substrate 21. Hence, connecting layer 22 can be securely protected.

Combined substrate 21 may further include: a metal layer (backside electrode 26) formed on the single-crystal semiconductor member (SiC single-crystal substrate 1) at its surface (backside surface) to be connected to supporting base 20 through connecting layer 22 as shown in FIG. 29.

In this case, the metal layer (backside electrode 26) is formed in advance on the surface (backside surface) of the single-crystal semiconductor member (SiC single-crystal substrate 1) to be connected to supporting base 20. Accordingly, when manufacturing a semiconductor device using combined substrate 21, an ohmic junction is formed, by heat treatment in the process of manufacturing the semiconductor device, at a portion at which the single-crystal semiconductor member (SiC single-crystal substrate 1) and the metal layer (backside electrode 26) are brought into contact with each other. Hence, in the semiconductor device formed using combined substrate 21, the metal layer (backside electrode 26) can be used as an electrode.

In combined substrate 21, a plurality of the single-crystal semiconductor members (SiC single-crystal substrates 1) are connected to supporting base 20 through connecting layer 22. The plurality of single-crystal semiconductor members (SiC single-crystal substrates 1) may be arranged side by side on the surface of supporting base 20. Further, it is preferable to form a gap between two single-crystal semiconductor members (SiC single-crystal substrates 1) disposed adjacent to each other as shown in FIG. 12 and the like. In this case, through the gap, oxidizing atmosphere such as oxygen plasma surely reaches connecting layer 22 when separating the single-crystal semiconductor member (SiC single-crystal substrate 1) from supporting base 20 in combined substrate 21. Thus, the single-crystal semiconductor member (SiC single-crystal substrate 1) can be securely separated from supporting base 20.

In combined substrate 21, supporting base 20 may have a quadrangular planar shape as shown in FIG. 12, FIG. 24, or the like. Also, it is preferable to connect the plurality of single-crystal semiconductor members (SiC single-crystal substrates 1) to supporting base 20 through connecting layer 22. Further, the single-crystal semiconductor member (SiC single-crystal substrate 1) preferably also has a quadrangular planar shape. In this case, when connecting the plurality of single-crystal semiconductor members (SiC single-crystal substrates 1) to one supporting base 20, the single-crystal semiconductor members (SiC single-crystal substrates 1) to be connected thereto can be arranged to exist even at the corners of the supporting base 20. Accordingly, the number of the single-crystal semiconductor members (SiC single-crystal substrates 1) that can be manufactured at one time can be increased, thereby realizing a combined substrate 21 allowing for efficient manufacturing of semiconductor devices.

In the combined substrate, the single-crystal semiconductor member (SiC single-crystal substrate 1) may be made of a material containing one of silicon carbide and nitride semiconductor. Supporting base 20 may be made of a material containing at least one selected from a group consisting of silicon carbide, alumina, sapphire, silicon, and silicon nitride. In the case where such materials are used, the connection between connecting layer 22 containing carbon and each of the single-crystal semiconductor member (SiC single-crystal substrate 1) and supporting base 20 can be maintained even under relatively high temperature environment, and combined substrate 21 capable of withstanding a process of high temperature can be realized.

In combined substrate 21, supporting base 20 may be provided with a through hole (opening 41) as shown in FIG. 19 to FIG. 23. The single-crystal semiconductor member (SiC single-crystal substrate 1) may be disposed in the through hole (stepped portion 42 of opening 41). In this case, the single-crystal semiconductor member (SiC single-crystal substrate 1) is disposed in stepped portion 42 of opening 41 of supporting base 20. Hence, connecting layer 22 is disposed at the outer circumference of the single-crystal semiconductor member (portion of SiC single-crystal substrate 1 opposite to the inner wall of stepped portion 42). Hence, when separating the single-crystal semiconductor member (SiC single-crystal substrate 1) and supporting base 20 from each other, oxidizing atmosphere can readily reach connecting layer 22, thereby securely decomposing connecting layer 22.

Further, in the above-described first and second embodiments, a counterbore (recess) may be formed on the surface of supporting base 20 in advance to facilitate positioning of SiC single-crystal substrate 1. For example, the recess preferably has a planar shape corresponding to that of SiC single-crystal substrate 1, and has a size capable of receiving the backside surface of SiC single-crystal substrate 1 therein.

Further, connecting layer 22 between SiC single-crystal substrate 1 and supporting base 20 may be disposed entirely on the surfaces (connection interface) of SiC single-crystal substrate 1 and supporting base 20 facing each other, but may be disposed in only a part of the connection interface (for example, only at the outer circumferential portion of the connection interface as shown in FIG. 8 or FIG. 16, or only a part of the outer circumferential portion, or only at a central portion of the connection interface, or one or more locations in the connection interface).

The embodiments and examples disclosed herein are illustrative and non-restrictive in any respect. The scope of the present invention is defined by the terms of the claims, rather than the embodiments described above, and is intended to include any modifications within the scope and meaning equivalent to the terms of the claims.

### INDUSTRIAL APPLICABILITY

The present invention is particularly advantageously applicable to a combined substrate constructed by combining a single-crystal semiconductor member such as a SiC single-crystal substrate or a GaN single-crystal substrate with a supporting base, as well as a semiconductor device manufactured using the combined substrate.

### REFERENCE SIGNS LIST

1: single-crystal substrate; 2: p⁻ type epitaxial layer; 3: n type epitaxial layer; 4: p⁺ type semiconductor layer; 5: source region layer; 6: p type epitaxial layer; 7: p⁺ type gate region layer; 9: drain region layer; 10, 111: source electrode; 11, 110: gate electrode; 12, 112: drain electrode; 20: supporting base; 21: combined substrate; 22: connecting layer; 23: epitaxial layer; 25: second supporting base; 26: backside electrode; 27: arrow; 30: element; 41: opening; 42: stepped portion; 101: semiconductor device; 121: buffer layer; 122: breakdown voltage holding layer; 123: p region; 124: n⁺ region; 125: p⁺ region; 126: oxide film; 127: upper source electrode.

1. A method for manufacturing a semiconductor device, comprising the steps of:
preparing a single-crystal semiconductor member;
preparing supporting base;
connecting said supporting base and said single-crystal semiconductor member to each other through a connecting layer containing carbon;
forming an epitaxial layer on a surface of said single-crystal semiconductor member;
forming a semiconductor element using said epitaxial layer;
separating said single-crystal semiconductor member from said supporting base by oxidizing and accordingly decomposing said connecting layer after the step of forming said semiconductor element; and
dividing said single-crystal semiconductor member separated from said supporting base.

2. The method for manufacturing the semiconductor device according to claim 1, wherein said single-crystal semiconductor member has a thickness equal to or smaller than 100 μm and has a carrier concentration equal to or greater than 1×10¹⁸ cm⁻³.

3. The method for manufacturing the semiconductor device according to claim 1, further comprising the steps of:
forming a protective film to cover an exposed surface of said connecting layer after the step of connecting and before the step of forming said semiconductor element; and
removing said protective film after the step of forming said semiconductor element and before the step of separating.

4. The method for manufacturing the semiconductor device according to claim 3, wherein said protective film is made of a material containing at least one selected from a group consisting of silicon carbide, silicon oxide, silicon nitride, and aluminum oxide.

5. The method for manufacturing the semiconductor device according to claim 1, wherein the step of preparing said single-crystal semiconductor member includes the step of forming a metal layer on said single-crystal semiconductor member at its surface to be connected to said supporting base through said connecting layer.

6. The method for manufacturing the semiconductor device according to claim 1, wherein:
in the step of preparing said single-crystal semiconductor member, a plurality of said single-crystal semiconductor members are prepared, and
in the step of connecting, said plurality of single-crystal semiconductor members are connected to said supporting base through said connecting layer.

7. The method for manufacturing the semiconductor device according to claim 1, wherein:
the step of forming said semiconductor element includes the step of applying a photoresist onto said epitaxial layer, and
in the step of applying said photoresist, one of a roller application method and a nozzle jetting application method is employed.

8. The method for manufacturing the semiconductor device according to claim 1, wherein said supporting base has a quadrangular planar shape.

9. The method for manufacturing the semiconductor device according to claim 1, wherein:
said single-crystal semiconductor member is made of a material containing one of silicon carbide and nitride semiconductor, and
said supporting base is made of a material containing at least one selected from a group consisting of silicon carbide, alumina, sapphire, silicon, and silicon nitride.

10. The method for manufacturing the semiconductor device according to claim 1, wherein said supporting base separated from said single-crystal semiconductor member in the step of separating is reused as the supporting base prepared in the step of preparing said supporting base.

11. The method for manufacturing the semiconductor device according to claim 1, wherein said supporting base is provided with a through hole capable of receiving said single-crystal semiconductor member therein.

12. A method for manufacturing a combined substrate, comprising the steps of:
preparing a single-crystal semiconductor member;
preparing a supporting base; and
connecting said supporting base and said single-crystal semiconductor member to each other through a connecting layer containing carbon.

13. The method for manufacturing the combined substrate according to claim 12, wherein said single-crystal semiconductor member has a thickness equal to or smaller than 100 μm and has a carrier concentration equal to or greater than 1×10¹⁸ cm⁻³.

14. The method for manufacturing the combined substrate according to claim 12, further comprising the step of forming a protective film to cover an exposed surface of said connecting layer.

15. The method for manufacturing the combined substrate according to claim 12, wherein the step of preparing said single-crystal semiconductor member includes the step of forming a metal layer on said single-crystal semiconductor member at its surface to be connected to said supporting base through said connecting layer.

16. The method for manufacturing the combined substrate according to claim 12, wherein:
in the step of preparing said single-crystal semiconductor member, a plurality of said single-crystal semiconductor members are prepared, and
in the step of connecting, said plurality of single-crystal semiconductor members are connected to said supporting base through said connecting layer.

17. The method for manufacturing the combined substrate according to claim 12, wherein:
said single-crystal semiconductor member is made of a material containing one of silicon carbide and nitride semiconductor, and
said supporting base is made of a material containing at least one selected from a group consisting of silicon carbide, alumina, sapphire, silicon, and silicon nitride.

18. A semiconductor device comprising:
a supporting base;
a single-crystal semiconductor layer connected onto a surface of said supporting base through a connecting layer containing carbon; and
an electrode formed on said single-crystal semiconductor layer.

19. The semiconductor device according to claim 18, wherein said supporting base is made of a conductive material.

20. The semiconductor device according to claim 18, wherein:
said single-crystal semiconductor layer is made of a material containing one of silicon carbide and nitride semiconductor, and
said supporting base is made of a material containing at least one selected from a group consisting of silicon carbide, alumina, sapphire, silicon, and silicon nitride.

21. A combined substrate comprising:
a supporting base; and
a single-crystal semiconductor member connected onto a surface of said supporting base through a connecting layer containing carbon.

22. The combined substrate according to claim 21, further comprising an epitaxial layer formed on a surface of said single-crystal semiconductor member.

23. The combined substrate according to claim 21, wherein said single-crystal semiconductor member has a thickness equal to or smaller than 100 μm and has a carrier concentration equal to or greater than 1×10¹⁸ cm⁻³.

24. The combined substrate according to claim 21, further comprising a protective film formed to cover an exposed surface of said connecting layer.

25. The combined substrate according to claim 21, further comprising a metal layer formed on said single-crystal semiconductor member at its surface to be connected to said supporting base through said connecting layer.

26. The combined substrate according to claim 21, wherein a plurality of said single-crystal semiconductor members are connected to said supporting base through said connecting layer.

27. The combined substrate according to claim 21, wherein said single-crystal semiconductor member is made of a material containing one of silicon carbide and nitride semiconductor, and
said supporting base is made of a material containing at least one selected from a group consisting of silicon carbide, alumina, sapphire, silicon, and silicon nitride.
